(19) United States
(12) Patent Application Publication
(10) Pub. No.: US 2026/0101578 A1
(43) Pub. Date: Apr. 9, 2026

(54) INTEGRATED CIRCUIT DEVICE

(71) Applicant: Samsung Electronics Co., Ltd., Suwon-si (KR)

(72) Inventors: Hyunggoo Lee, Suwon-si (KR); Kyongbeom Koh, Suwon-si (KR); Kiil Kim, Suwon-si (KR)

(21) Appl. No.: 19/098,215

(22) Filed: Apr. 2, 2025

(30) Foreign Application Priority Data
Oct. 4, 2024 (KR) 10-2024-0134984

(51) Int. Cl. H10D 84/83; H01L 23/528; H10D 30/00; H10D 30/01; H10D 30/43; H10D 62/10; H10D 62/13; H10D 64/23; H10D 84/01

(52) U.S. Cl. CPC H10D 84/832; H10D 30/43; H10D 30/502; H10D 62/121; H10D 62/151; H10D 64/256; H10D 84/8312; H10W 20/427; H10W 20/435; H10D 30/014; H10D 30/0191; H10D 84/0149

(57) ABSTRACT

An integrated circuit device includes a gate line, a source/drain region adjacent to the gate line in a first direction, a backside via contact connected to the source/drain region, a backside power rail integrally connected to the backside via contact and spaced apart from the source/drain region in a second direction with the backside via contact therebetween, and a backside insulating pattern overlapping the gate line in the second direction and contacting a sidewall of the backside power rail in the first direction, wherein the backside insulating pattern includes a first backside insulating portion having a gradually increasing width in the first direction with an increasing distance from the gate line, and a second backside insulating portion integrally connected to the first backside insulating portion and having a gradually decreasing width in the first direction with an increasing distance from the gate line.

### CROSS-REFERENCE TO RELATED APPLICATION

This application is based on and claims priority under 35 U.S.C. § 119 to Korean Patent Application No. 10-2024-0134984, filed on Oct. 4, 2024, in the Korean Intellectual Property Office, the disclosure of which is incorporated by reference for all purposes as if fully set forth herein in its entirety.

### FIELD

The present disclosure relates to an integrated circuit device, and more particularly, to an integrated circuit device including a backside contact structure.

### BACKGROUND

Due to the advance of electronics technology, integrated circuit devices have been rapidly down-scaled. Because highly down-scaled integrated circuit devices still require high operation speeds and accuracy in performing operations, a backside power distribution network may be used to provide more freedom for the location of both signal lines and power distribution lines.

### SUMMARY

The present disclosure provides an integrated circuit device having a structure allowing the reliability of the integrated circuit device to be secured and a fabrication process of the integrated circuit device to be simplified, when the integrated circuit device includes a plurality of wiring structures arranged in a reduced area due to down-scaling.

According to an embodiment of the present disclosure, there is provided an integrated circuit device including a gate line, a source/drain region adjacent to the gate line in a first direction, a backside via contact connected to the source/drain region, a backside power rail integrally connected to the backside via contact, the backside power rail spaced apart from the source/drain region in a second direction with the backside via contact therebetween, wherein the second direction is perpendicular to the first direction, and a backside insulating pattern overlapping the gate line in the second direction, the backside insulating pattern contacting a sidewall of the backside power rail in the first direction, wherein the backside insulating pattern includes a first backside insulating portion and a second backside insulating portion, the first backside insulating portion having a gradually increasing width in the first direction with an increasing distance from the gate line, and the second backside insulating portion having a gradually decreasing width in the first direction with an increasing distance from the gate line.

According to another embodiment of the present disclosure, there is provided an integrated circuit device including a pair of gate lines adjacent to each other in a first direction and each extending in a second direction, wherein the first direction intersects with the second direction, a source/drain region between the pair of gate lines, a backside via contact connected to the source/drain region, a backside power rail integrally connected to the backside via contact, the backside power rail spaced apart from the source/drain region in a third direction with the backside via contact therebetween, wherein the third direction is perpendicular to the first direction and the second direction, and a pair of backside isolation structures respectively overlapping the pair of gate lines in the third direction, wherein each of the pair of backside isolation structures is contacting a sidewall of the backside power rail in the first direction, and at least one backside isolation structure selected from the pair of backside isolation structures includes a first backside insulating portion and a second backside insulating portion integrally connected to the first backside insulating portion, the first backside insulating portion having a gradually increasing width in the first direction with an increasing distance from a gate line selected from the pair of gate lines, and the second backside insulating portion having a gradually decreasing width in the first direction with an increasing distance from the selected gate line.

According to another embodiment of the present disclosure, there is provided an integrated circuit device including a pair of gate lines adjacent to each other in a first direction and each extending in a second direction, wherein the first direction intersects with the second direction, a plurality of source/drain regions including a first source/drain region between the pair of gate lines, a plurality of backside via contacts including a first backside via contact connected to the first source/drain region, a plurality of backside power rails including a first backside power rail integrally connected to the first backside via contact, the first backside power rail spaced apart from the first source/drain region in a third direction with the first backside via contact therebetween, a pair of backside insulating patterns respectively overlapping the pair of gate lines in the third direction, and a pair of semiconductor blocks each arranged between the first backside via contact and each of the pair of backside insulating patterns, wherein a portion of each of the pair of backside insulating patterns is contacting a sidewall of the first backside power rail in the first direction, each of the pair of backside insulating patterns includes a first backside insulating portion and a second backside insulating portion integrally connected to the first backside insulating portion, the first backside insulating portion having a gradually increasing width in the first direction with an increasing distance from a gate line selected from the pair of gate lines, and the second backside insulating portion having a gradually decreasing width in the first direction with an increasing distance from the selected gate line, and each of the pair of semiconductor blocks includes a semiconductor curved-surface that is contacting the first backside power rail.

### BRIEF DESCRIPTION OF THE DRAWINGS

Embodiments will be more clearly understood from the following detailed description taken in conjunction with the accompanying drawings in which:

FIG. 1 is a schematic plan view of an example of a cell block of an integrated circuit device, according to embodiments;

FIG. 2 is a planar layout diagram illustrating an integrated circuit device according to embodiments;

FIG. 3 is a cross-sectional view of the integrated circuit device of FIG. 2, taken along a line X1-X1′ of FIG. 2;

FIG. 4 is a cross-sectional view of the integrated circuit device of FIG. 2, taken along a line Y1-Y1′ of FIG. 2;

FIG. 5 is a cross-sectional view of the integrated circuit device of FIG. 2, taken along a line Y2-Y2′ of FIG. 2;

FIG. 6 is an enlarged cross-sectional view of a region EX1 of FIG. 3;

FIG. 7 is a planar layout diagram illustrating an integrated circuit device according to some embodiments;

FIG. 8 is a cross-sectional view of the integrated circuit device of FIG. 7, taken along a line X1-X1′ of FIG. 7;

FIG. 9 is a planar layout diagram illustrating an integrated circuit device according to some embodiments;

FIG. 10 is a cross-sectional view of the integrated circuit device of FIG. 9, taken along a line X3-X3′ of FIG. 9;

FIGS. 11A to 22C are cross-sectional views respectively illustrating a sequence of processes of a method of fabricating an integrated circuit device, according to embodiments, and in particular, FIGS. 11A, 12A, 13A, 14A, 15A, 16A, 17A, 18A, 19A, 20A, 21A, and 22A are cross-sectional views respectively illustrating cross-sectional structures of a region corresponding to the cross-section taken along the line X1-X1′ of FIG. 2, according to the sequence of processes, FIGS. 11B, 12B, 13B, 14B, 15B, 16B, 17B, 18B, 19B, 20B, 21B, and 22B are cross-sectional views respectively illustrating cross-sectional structures of a region corresponding to the cross-section taken along the line Y1-Y1′ of FIG. 2, according to the sequence of processes, and FIGS. 14C, 15C, 19C, 20C, 21C, and 22C are cross-sectional views respectively illustrating cross-sectional structures of a region corresponding to the cross-section taken along the line Y2-Y2′ of FIG. 2, according to the sequence of processes; and

FIGS. 23A to 26C are cross-sectional views illustrating, in more detail, a process of forming a via hole and a line hole in the method of fabricating an integrated circuit device, which is described with reference to FIGS. 11A to 22C, and in particular, FIGS. 23A, 24A, 25A, and 26A are cross-sectional views respectively illustrating cross-sectional structures of a region EX11 of FIG. 21A in an area corresponding to the cross-section taken along the line X1-X1′ of FIG. 2, according to the sequence of processes, FIGS. 23B, 24B, 25B, and 26B are cross-sectional views respectively illustrating cross-sectional structures of a region EX12 of FIG. 21B in an area corresponding to the cross-section taken along the line Y1-Y1′ of FIG. 2, according to the sequence of processes, and FIGS. 23C, 24C, 25C, and 26C are cross-sectional views respectively illustrating cross-sectional structures of a region EX13 of FIG. 21C in an area corresponding to the cross-section taken along the line Y2-Y2′ of FIG. 2, according to the sequence of processes.

### DETAILED DESCRIPTION OF EMBODIMENTS

Hereinafter, a semiconductor device and a method of manufacturing the same according to some embodiments of the present disclosure will be described in detail with reference to the drawings Like components are denoted by like reference numerals throughout the specification, and repeated descriptions thereof are omitted.

The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

It will be understood that spatially relative terms such as “above,” “upper,” “upper portion,” “upper surface,” “below,” “lower,” “lower portion,” “lower surface,” “side surface,” and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

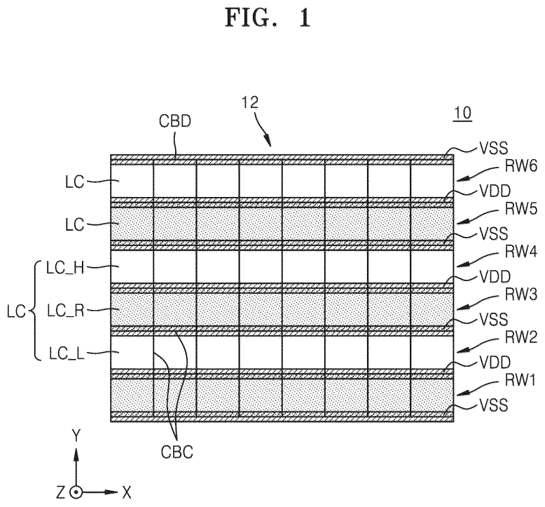

FIG. 1 is a schematic plan view of an example of a cell block 12 of an integrated circuit device 10 according to embodiments.

Referring to FIG. 1, the cell block 12 of the integrated circuit device 10 may include a plurality of cells LC including circuit patterns for constituting various circuits. The plurality of cells LC may be arranged in a matrix in a width direction (an X direction in FIG. 1) and a height direction (a Y direction in FIG. 1) in a cell block 12.

The plurality of cells LC may include a circuit pattern having a layout designed by a Place and Route (PnR) technique to perform at least one logical function. The plurality of cells LC may perform various logical functions. In some embodiments, the plurality of cells LC may include a plurality of standard cells. In some embodiments, at least some of the plurality of cells LC may perform the same logical function. In some embodiments, at least some of the plurality of cells LC may respectively perform different logical functions.

The plurality of cells LC may include various types of logic cells including a plurality of circuit elements. For example, each of the plurality of cells LC may include, but is not limited to, an AND, a NAND, an OR, a NOR, an exclusive OR (XOR), an exclusive NOR (XNOR), an inverter (INV), an adder (ADD), a buffer (BUF), a delay (DLY), a filter (FIL), a multiplexer (MXT/MXIT), an OR/AND/INVERTER (OAI), an AND/OR (AO), an AND/OR/INVERTER (AOI), a D flip-flop, a reset flip-flop, a master-slave flip-flop, a latch, or a combination thereof.

In the cell block 12, at least some of the plurality of cells LC constituting one row (that is, RW1, RW2, RW3, RW4, RW5, or RW6) in the width direction (the X direction in FIG. 1) may have the same width. In addition, at least some of the plurality of cells LC constituting one row (that is, RW1, RW2, RW3, RW4, RW5, or RW6) may each have the same height. However, the inventive concept is not limited to the example shown in FIG. 1, and at least some of the plurality of cells LC constituting one row (that is, RW1, RW2, RW3, RW4, RW5, or RW6) may have different widths and heights from each other.

The area of each of the plurality of cells LC in the cell block 12 of the integrated circuit device 10 may be defined by a cell boundary CBD. A cell interface portion CBC, at which respective cell boundaries CBD meet each other, may be arranged between two adjacent cells LC in the width direction (the X direction in FIG. 1) or the height direction (the Y direction in FIG. 1) from among the plurality of cells LC.

In some embodiments, two adjacent cells LC in the width direction, among the plurality of cells LC constituting one row (that is, RW1, RW2, RW3, RW4, RW5, or RW6), may be in contact with each other at the cell interface portion CBC without a separation distance therebetween. In some embodiments, two adjacent cells LC in the width direction, among the plurality of cells LC constituting one row (that is, RW1, RW2, RW3, RW4, RW5, or RW6), may be apart from each other with a certain separation distance therebetween.

In some embodiments, in the plurality of cells LC constituting one row (that is, RW1, RW2, RW3, RW4, RW5, or RW6), two adjacent cells LC may perform the same function. In this case, the two adjacent cells LC may have the same structure. In some embodiments, in the plurality of cells LC constituting one row (that is, RW1, RW2, RW3, RW4, RW5, or RW6), two adjacent cells LC may respectively perform different functions.

In some embodiments, one cell LC selected from the plurality of cells LC, which are included in the cell block 12 of the integrated circuit device 10, and another cell LC adjacent to the selected cell LC in the height direction (the Y direction in FIG. 1) may have symmetric structures to each other about the cell interface portion CBC therebetween. For example, a reference logic cell LC_R in a third row RW3 and a lower logic cell LC_L in a second row RW2 may have symmetric structures to each other about the cell interface portion CBC therebetween. In addition, the reference logic cell LC_R in the third row RW3 and an upper logic cell LC_H in a fourth row RW4 may have symmetric structures to each other about the cell interface portion CBC therebetween. Although FIG. 1 illustrates the cell block 12 including six rows (that is, RW1, RW2, RW3, RW4, RW5, and RW6), this is only an example, and the cell block 12 may include rows in various numbers selected as needed, and one row may include logic cells in various numbers selected as needed.

A line selected from among a plurality of ground lines VSS and a plurality of power lines VDD may be arranged between a plurality of rows (that is, RW1, RW2, RW3, RW4, RW5, and RW6), which each include the plurality of cells LC arranged in a line in the width direction (the X direction in FIG. 1). The plurality of ground lines VSS and the plurality of power lines VDD may each extend in a first horizontal direction (the X direction) and may be alternately arranged apart from each other in a second horizontal direction (the Y direction). The second horizontal direction (the Y direction) is a direction orthogonal to the first horizontal direction (the X direction). The term “orthogonal” encompasses substantially orthogonal. The term “perpendicular” encompasses substantially perpendicular. However, the inventive concept is not limited thereto. For example, the second horizonal direction may simply intersect the first horizontal direction. Therefore, each of the plurality of ground lines VSS and the plurality of power lines VDD may be arranged to overlap the cell boundary CBD of the cell LC, the cell boundary CBD extending in the second horizontal direction (the Y direction).

Components or layers described with reference to “overlap” in a particular direction may be at least partially obstructed by one another when viewed along a line extending in the particular direction or in a plane perpendicular to the particular direction.

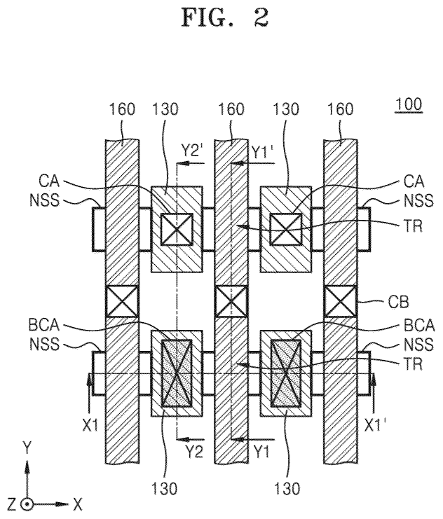

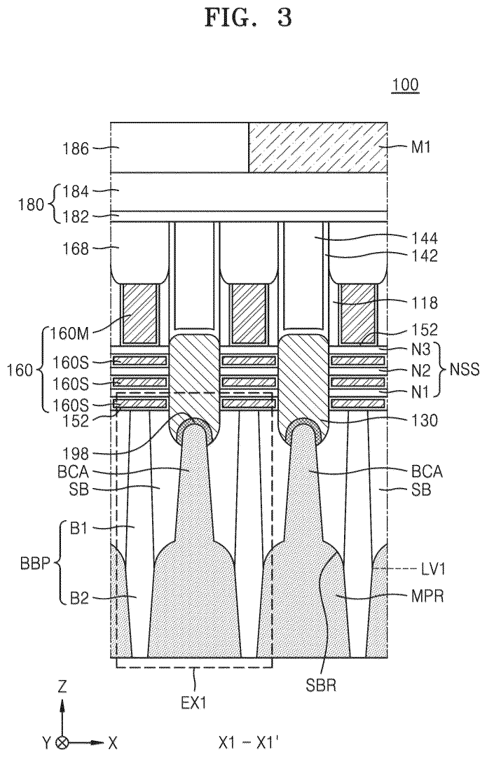

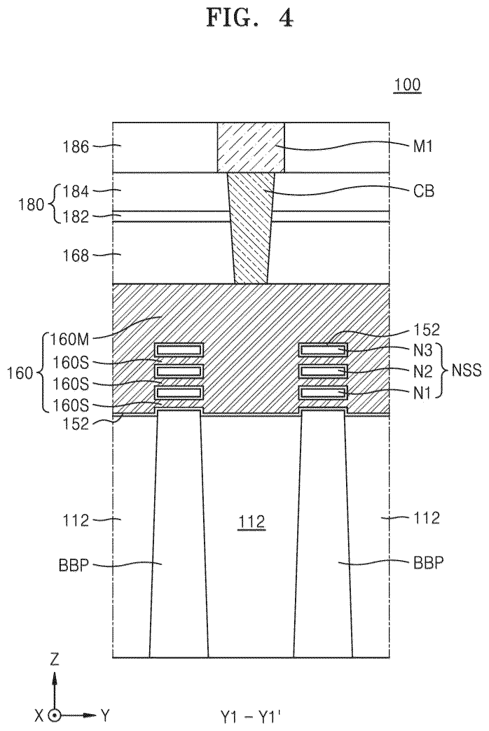

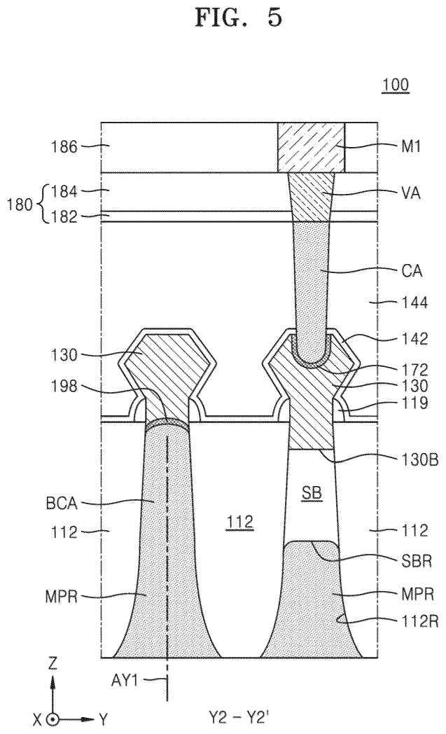

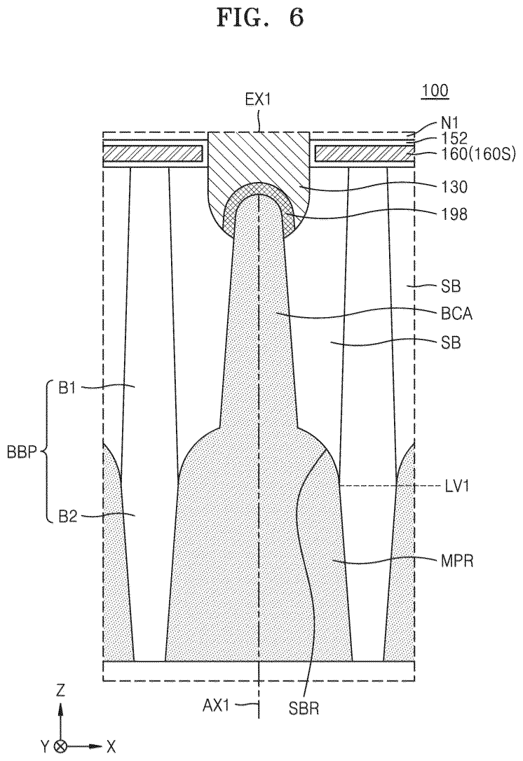

FIG. 2 is a planar layout diagram illustrating an integrated circuit device 100 according to embodiments. FIG. 3 is a cross-sectional view of the integrated circuit device 100, taken along a line X1-X1′ of FIG. 2. FIG. 4 is a cross-sectional view of the integrated circuit device 100, taken along a line Y1-Y1′ of FIG. 2. FIG. 5 is a cross-sectional view of the integrated circuit device 100, taken along a line Y2-Y2′ of FIG. 2. FIG. 6 is an enlarged cross-sectional view of a region EX1 of FIG. 3.

The integrated circuit device 100 including a nanosheet transistor TR, which has a gate-all-around (GAA) structure including a nanowire or nanosheet-shaped channel region and a gate surrounding the channel region, is described with reference to FIGS. 2 to 6. The components shown in FIGS. 2 to 6, in the integrated circuit device 100, may constitute a portion of the plurality of cells LC shown in FIG. 1.

The term “surrounding” or “covering” or “filling” as may be used herein may not require completely surrounding or covering or filling the described elements or layers, but may, for example, refer to partially surrounding or covering or filling the described elements or layers, for example, with voids, spaces, or other discontinuities throughout.

Referring to FIGS. 2 to 6, the integrated circuit device 100 may include a plurality of nanosheet stacks NSS, a plurality of gate lines 160 respectively surrounding the plurality of nanosheet stacks NSS, and a plurality of source/drain regions 130 arranged one-by-one between two adjacent gate lines 160 from among the plurality of gate lines 160. The plurality of gate lines 160, the plurality of nanosheet stacks NSS, and the plurality of source/drain regions 130 may constitute a plurality of nanosheet transistors TR.

The plurality of nanosheet stacks NSS may be arranged apart from each other in the first horizontal direction (the X direction) and the second horizontal direction (the Y direction), which are orthogonal to each other. Each of the plurality of nanosheet stacks NSS may include a first nanosheet N1, a second nanosheet N2, and a third nanosheet N3, which are sequentially stacked in the stated order in a vertical direction (a Z direction) to be apart from each other. The vertical direction (the Z direction) is a direction orthogonal to each of the first horizontal direction (the X direction) and the second horizontal direction (the Y direction). The first to third nanosheets N1, N2, and N3, which are included in a nanosheet stack NSS, may each constitute a channel region.

The plurality of gate lines 160 may be apart from each other in the first horizontal direction (the X direction) and may extend lengthwise in the second horizontal direction (the Y direction). Each of the plurality of gate lines 160 may surround the first to third nanosheets N1, N2, and N3 of the nanosheet stack NSS. Each of the plurality of gate lines 160 may be surrounded by a gate dielectric film 152.

The plurality of source/drain regions 130 may be arranged one-by-one between two adjacent gate lines 160 from among the plurality of gate lines 160. Some source/drain regions 130 selected from the plurality of source/drain regions 130 may each be connected to a backside via contact BCA. The backside via contact BCA may pass through, in the vertical direction (the Z direction), a lower portion of a source/drain region 130 corresponding thereto from a back side of the corresponding source/drain region 130.

As shown in FIGS. 2 and 5, some other source/drain regions 130 selected from the plurality of source/drain regions 130 may each be connected to a frontside source/drain contact CA. The frontside source/drain contact CA may pass through an upper portion of a source/drain region 130 corresponding thereto in the vertical direction (the Z direction) from a front side of the corresponding source/drain region 130.

Respective frontside surfaces of the plurality of source/drain regions 130 may be covered by an insulating liner 142 and an inter-gate dielectric 144. The respective frontside surfaces of the plurality of source/drain regions 130 may be in contact with the insulating liner 142. The frontside source/drain contact CA may pass through the inter-gate dielectric 144 and the insulating liner 142 in the vertical direction (the Z direction) and may be configured to be connected to the corresponding source/drain region 130.

A frontside metal silicide film 172 may be arranged between the frontside source/drain contact CA and a source/drain region 130 connected to the frontside source/drain contact CA from among the plurality of source/drain regions 130. The frontside source/drain contact CA may be configured to be connected to the corresponding source/drain region 130 via the frontside metal silicide film 172.

A backside lower surface of each of the plurality of source/drain regions 130, for example, a backside lower surface 130B shown in FIG. 5, may be apart from the inter-gate dielectric 144 and the insulating liner 142. A backside metal silicide film 198 may be arranged between the backside via contact BCA and a source/drain region 130 connected to the backside via contact BCA from among the plurality of source/drain regions 130. The backside via contact BCA may be configured to be connected to the corresponding source/drain region 130 via the backside metal silicide film 198.

Each of the plurality of source/drain regions 130 may include a semiconductor layer including a dopant. In some embodiments, the integrated circuit device 100 may include a nanosheet transistor TR (see FIG. 2) including a PMOS transistor, and each of the plurality of source/drain regions 130 may include a Si₁₋ₓGeₓ layer (where x≠0) doped with a p-type dopant. The p-type dopant may include, but is not limited to, at least one selected from boron (B) and gallium (Ga). For example, the plurality of source/drain regions 130 may each include boron (B) as the p-type dopant. In this case, in each of the plurality of source/drain regions 130, a doping concentration of boron (B) may be, but is not limited to, about 8×10²⁰ atom/cm³ to about 2×10²¹ atom/cm³.

In some embodiments, the integrated circuit device 100 may include a nanosheet transistor TR (see FIG. 2) including an NMOS transistor, and each of the plurality of source/drain regions 130 may include a Si layer doped with an n-type dopant. The n-type dopant may include, but is not limited to, at least one selected from phosphorus (P), arsenic (As), and antimony (Sb). For example, the plurality of source/drain regions 130 may each include phosphorus (P) as the n-type dopant. In this case, in each of the plurality of source/drain regions 130, a doping concentration of phosphorus (P) may be, but is not limited to, about 8×10²⁰ atom/cm³ to about 1×10²¹ atom/cm³.

As shown in FIGS. 2 and 5, in the plurality of source/drain regions 130 of the integrated circuit device 100, the source/drain region 130 connected to the backside via contact BCA may be different from the source/drain region 130 connected to the frontside source/drain contact CA. That is, the source/drain region 130 connected to the backside via contact BCA may be different from the source/drain region 130 connected to the frontside source/drain contact CA. However, the inventive concept is not limited thereto. For example, the frontside source/drain contact CA and the backside via contact BCA may be present at one source/drain region 130.

As shown in FIGS. 3, 4, and 6, the integrated circuit device 100 may include a plurality of backside insulating patterns BBP, which are arranged in a line in the first horizontal direction (the X direction) and each extend lengthwise in the second horizontal direction (the Y direction), a plurality of backside via contacts BCA separated from each other in the first horizontal direction (the X direction) by the plurality of backside insulating patterns BBP, and a plurality of backside power rails MPR separated from each other in the first horizontal direction (the X direction) by the plurality of backside insulating patterns BBP. Each of the plurality of backside via contacts BCA may be integrally connected to each backside power rail MPR selected from the plurality of backside power rails MPR. Here integrally connected includes being made from the same material layer during the manufacturing of the integrated circuit device. As shown in FIG. 3, the plurality of backside via contacts BCA may be arranged one-by-one in the first horizontal direction (the X direction) between the plurality of backside insulating patterns BBP, and the plurality of backside power rails MPR may be arranged one-by-one in the first horizontal direction (the X direction) between the plurality of backside insulating patterns BBP. Herein, each of the plurality of backside insulating patterns BBP may be referred to as a backside isolation structure.

In the integrated circuit device 100, a plurality of nanosheet stacks NSS may be arranged respectively apart from the plurality of backside insulating patterns BBP in the vertical direction (the Z direction). Each of the plurality of source/drain regions 130 may be in contact with the first to third nanosheets N1, N2, and N3, which are included in a nanosheet stack NSS adjacent to each source/drain region 130 from among the plurality of nanosheet stacks NSS.

Each of the plurality of backside insulating patterns BBP may be in contact with a pair of backside power rails MPR that are selected from the plurality of backside power rails MPR and adjacent to each other. Each of the plurality of backside insulating patterns BBP may extend lengthwise in the vertical direction (the Z direction) from a space between the pair of backside power rails MPR adjacent to each other toward each gate line 160 selected from the plurality of gate lines 160. In some embodiments, each of the plurality of backside insulating patterns BBP may include a nitrogen-containing insulating film. For example, each of the plurality of backside insulating patterns BBP may include, but is not limited to, a silicon nitride (SiN) film, a silicon carbonitride (SiCN) film, a silicon oxycarbonitride (SiOCN) film, or a combination thereof.

The backside via contact BCA may extend lengthwise in the vertical direction (the Z direction) between a pair of backside insulating patterns BBP adjacent to each other from among the plurality of backside insulating patterns BBP. A backside power rail MPR integrally connected to the backside via contact BCA, among the plurality of backside power rails MPR, may be apart from a source/drain region 130, which corresponds to the backside power rail MPR, in the vertical direction (the Z direction) with the backside via contact BCA therebetween. Each of the plurality of backside power rails MPR may extend lengthwise in the second horizontal direction (the Y direction).

In some embodiments, the backside via contact BCA and the backside power rail MPR may be simultaneously formed in a single process, and the backside via contact BCA and the backside power rail MPR may include the same material. In some embodiments, the backside via contact BCA and the backside power rail MPR may include a single metal. In some embodiments, each of the backside via contact BCA and the backside power rail MPR may include a metal plug and a conductive barrier film surrounding the metal plug. The metal plug may include, but is not limited to, molybdenum (Mo), tungsten (W), cobalt (Co), ruthenium (Ru), manganese (Mn), titanium (Ti), tantalum (Ta), aluminum (Al), copper (Cu), a combination thereof, or an alloy thereof. The conductive barrier film may include a metal or a conductive metal nitride. For example, the conductive barrier film may include, but is not limited to, Ti, Ta, W, TiN, TaN, WN, WCN, TiSiN, TaSiN, WSiN, or a combination thereof.

The plurality of backside insulating patterns BBP may include a pair of backside insulating patterns BBP, which are respectively arranged on both sides of one backside via contact BCA with the one backside via contact BCA therebetween in the first horizontal direction (the X direction). Each of the pair of backside insulating patterns BBP may extend lengthwise in the vertical direction (the Z direction) at a position overlapping each gate line 160 selected from the plurality of gate lines 160 in the vertical direction (the Z direction). The pair of backside insulating patterns BBP may each include a portion facing the backside via contact BCA in the first horizontal direction (the X direction). Each of the plurality of backside insulating patterns BBP may be in contact with a gate dielectric film 152.

As shown in FIGS. 3 and 6, each of the plurality of backside insulating patterns BBP may be in contact with a sidewall of the backside power rail MPR in the first horizontal direction (the X direction). Each of the plurality of backside insulating patterns BBP may include a first backside insulating portion B1 and a second backside insulating portion B2, which overlap each other in the vertical direction (the Z direction). The first backside insulating portion B1 of each of the plurality of backside insulating patterns BBP may have a shape having a gradually increasing width in the first horizontal direction (the X direction) with an increasing distance from a gate line 160 corresponding thereto in the vertical direction (the Z direction). The second backside insulating portion B2 of each of the plurality of backside insulating patterns BBP may be integrally connected to the first backside insulating portion B1 and may have a shape having a gradually decreasing width in the first horizontal direction (the X direction) with an increasing distance from a gate line 160 corresponding thereto in the vertical direction (the Z direction).

The second backside insulating portion B2 of the backside insulating pattern BBP may be apart from the gate line 160 in the vertical direction with the first backside insulating portion B1 therebetween, and each of the plurality of backside power rails MPR may be in contact with only the second backside insulating portion B2 out of the first backside insulating portion B1 and the second backside insulating portion B2 in the backside insulating pattern BBP adjacent to each backside power rail MPR. The backside via contact BCA may be apart from the backside insulating pattern BBP in the first horizontal direction (the X direction).

In each of the plurality of backside insulating patterns BBP, the width of a portion contacting the sidewall of the backside power rail MPR, in the first horizontal direction (the X direction), may gradually decrease with an increasing distance from the gate line 160 in the vertical direction (the Z direction).

As shown in FIGS. 3 and 6, the integrated circuit device 100 may include a plurality of semiconductor blocks SB. Some semiconductor blocks SB from among the plurality of semiconductor blocks SB may each cover the sidewall of the backside via contact BCA in the first horizontal direction (the X direction). In some embodiments, the semiconductor blocks SB from among the plurality of semiconductor blocks SB may each be in contact with the sidewall of the backside insulating pattern BBP in the first horizontal direction (the X direction). The semiconductor blocks SB from among the plurality of semiconductor blocks SB may each be arranged between the first backside insulating portion B1 of the backside insulating pattern BBP and the backside via contact BCA. In the first horizontal direction (the X direction), a sidewall of the first backside insulating portion B1 of the backside insulating pattern BBP may be in contact with the semiconductor block SB, and a sidewall of the second backside insulating portion B2 of the backside insulating pattern BBP may be in contact with the backside power rail MPR. A first vertical level LV1, which is a boundary between the first backside insulating portion B1 and the second backside insulating portion B2 of the backside insulating pattern BBP, may correspond to a position, at which a portion contacting the semiconductor block SB meets a portion contacting the backside power rail MPR, in the sidewall of the backside insulating pattern BBP. As used herein, the term “vertical level” refers to a distance in the vertical direction (the Z direction or the −Z direction) from the uppermost surface, which is closest to the gate line 160, of the backside insulating pattern BBP.

As shown in FIGS. 3 and 6, the plurality of semiconductor blocks SB may include a semiconductor block SB (which may be referred to as a first semiconductor block), which is arranged between the backside power rail MPR and the gate line 160, as shown in FIGS. 3 and 6, and a semiconductor block SB (which may be referred to as a second semiconductor block), which is arranged between the backside power rail MPR and the source/drain region 130, as shown in FIG. 5. The semiconductor block SB (that is, the second semiconductor block) between the backside power rail MPR and the source/drain region 130, among the plurality of semiconductor blocks SB, may be in contact with the backside lower surface 130B of the source/drain region 130 to which the frontside source/drain contact CA is connected.

At least some of the plurality of semiconductor blocks SB may each include a semiconductor curved-surface SBR contacting the backside power rail MPR. For example, the semiconductor block SB (that is, the first semiconductor block) between the backside power rail MPR and the gate line 160, as shown in FIGS. 3 and 6, may include a semiconductor curved-surface SBR contacting a partial surface, which is adjacent to the backside via contact BCA, of the backside power rail MPR. In addition, the semiconductor block SB (that is, the second semiconductor block) between the backside power rail MPR and the source/drain region 130, as shown in FIG. 5, may include a semiconductor curved-surface SBR contacting a surface, which faces the source/drain region 130 in the vertical direction (the Z direction), of the backside power rail MPR. In some embodiments, an insulating liner may be arranged between the semiconductor block SB and the backside via contact BCA and between the semiconductor curved-surface SBR of the semiconductor block SB and the backside power rail MPR.

Each of the plurality of semiconductor blocks SB may include silicon (Si). The plurality of semiconductor blocks SB may each be in contact with the gate dielectric film 152 covering the lowermost surface of the gate line 160. Herein, the lowermost surface of the gate line 160 refers to a surface, which is closest to the backside power rail MPR, of the gate line 160.

Each of the backside via contact BCA and the backside power rail MPR may have a gradually increasing width in the first horizontal direction (the X direction) with an increasing distance from the source/drain region 130 corresponding thereto in the vertical direction (the Z direction). The width of the backside via contact BCA in the first horizontal direction (the X direction) may be defined by the semiconductor block SB adjacent thereto. The backside power rail MPR may include a portion having a width, which is defined in the first horizontal direction (the X direction) by the semiconductor curved-surface SBR of the semiconductor block SB adjacent to the backside power rail MPR, and a portion having a width, which is defined in the first horizontal direction (the X direction) by the second backside insulating portion B2 of the backside insulating pattern BBP adjacent to the backside power rail MPR. The portion of the backside power rail MPR, which has a width defined in the first horizontal direction (the X direction) by the semiconductor curved-surface SBR of the semiconductor block SB adjacent thereto, may include a curved portion contacting the semiconductor curved-surface SBR of the semiconductor block SB. In the backside power rail MPR, each portion contacting the semiconductor curved-surface SBR of the semiconductor block SB and the portion contacting the second backside insulating portion B2 of the backside insulating pattern BBP may have a gradually increasing width in the first horizontal direction (the X direction) with an increasing distance from the source/drain region 130, which corresponds to the backside power rail MPR, in the vertical direction (the Z direction).

As shown in FIG. 4, in the second horizontal direction (the Y direction), both sidewalls of the backside insulating pattern BBP may be covered by a device isolation film 112. As shown in FIG. 5, in the second horizontal direction (the Y direction), both sidewalls of each of the backside via contact BCA and the backside power rail MPR may be covered by the device isolation film 112. In addition, both sidewalls of some semiconductor blocks SB in the second horizontal direction (the Y direction), among the plurality of semiconductor blocks SB, may be covered by the device isolation film 112.

As shown in FIG. 4, the device isolation film 112 may have a surface facing the gate line 160 with the gate dielectric film 152 therebetween and a surface contacting the backside insulating pattern BBP. In addition, as shown in FIG. 5, the device isolation film 112 may include a surface contacting the backside via contact BCA in the second horizontal direction (the Y direction), a surface contacting the backside power rail MPR in the second horizontal direction (the Y direction), and a surface contacting the semiconductor block SB in the second horizontal direction (the Y direction). The device isolation film 112 may include an oxide film, a nitride film, or a combination thereof. The device isolation film 112 may include a device isolation curved-surface 112R contacting the sidewall of the backside power rail MPR. In the second horizontal direction (the Y direction), a portion, which contacts the device isolation curved-surface 112R of the device isolation film 112, of the backside power rail MPR may have a gradually increasing width in the second horizontal direction (the Y direction) with an increasing distance from the source/drain region 130 corresponding to the backside power rail MPR in the vertical direction (the Z direction).

In some embodiments, as shown in FIGS. 3 and 6, in the first horizontal direction (the X direction), both sidewalls of the backside power rail MPR may have symmetric shapes to each other. For example, a cross-sectional shape of the backside power rail MPR in the first horizontal direction (the X direction) may include two side portions symmetric to each other about an extension line AX1 of a central axis, which extends in the vertical direction (the Z direction), of the backside via contact BCA integrally connected to the backside power rail MPR. Similarly, as shown in FIG. 5, a cross-sectional shape of the backside power rail MPR in the second horizontal direction (the Y direction) may include two side portions symmetric to each other about an extension line AY1 of a central axis, which extends in the vertical direction (the Z direction), of the backside via contact BCA integrally connected to the backside power rail MPR.

As shown in FIGS. 3 and 4, the plurality of backside insulating patterns BBP may overlap the plurality of nanosheet stacks NSS in the vertical direction (the Z direction). Each of the plurality of nanosheet stacks NSS may be arranged to be apart from the backside insulating pattern BBP in the vertical direction (the Z direction). As used herein, the term “nanosheet” refers to a conductive structure having a cross-section that is substantially perpendicular to a current-flowing direction. The nanosheet may also be understood as including a nanowire. Although the present example illustrates a configuration in which one nanosheet stack NSS includes three nanosheets, that is, the first nanosheet N1, the second nanosheet N2, and the third nanosheet N3, the inventive concept is not limited thereto. The number of nanosheets in the nanosheet stack NSS may be variously selected as needed.

In one nanosheet stack NSS, the first nanosheet N1, the second nanosheet N2, and the third nanosheet N3 may be located apart from each other in the vertical direction (the Z direction) to overlap each other in the vertical direction (the Z direction). Each of the first to third nanosheets N1, N2, and N3 of one nanosheet stack NSS may be surrounded by one gate line 160. Each of the first to third nanosheets N1, N2, and N3 of one nanosheet stack NSS may be used as a channel region of a nanosheet transistor TR (see FIG. 2). In some embodiments, each of the first to third nanosheets N1, N2, and N3 may include a Si layer, a SiGe layer, or a combination thereof. In some embodiments, the first to third nanosheets N1, N2, and N3 may include the same material. In some embodiments, respective thicknesses of the first to third nanosheets N1, N2, and N3 in the vertical direction (the Z direction) may be equal or similar to each other.

As shown in FIGS. 3 and 4, each of the plurality of gate lines 160 may be arranged over the backside insulating pattern BBP to cover a plurality of nanosheet stacks NSS and to surround the first to third nanosheets N1, N2, and N3. Each of the plurality of gate lines 160 may include a main gate portion 160M, which extends lengthwise in the second horizontal direction (Y direction) to cover an upper surface of the nanosheet stack NSS, and a plurality of sub-gate portions 160S, which are integrally connected to the main gate portion 160M and respectively fill separation spaces between the first to third nanosheets N1, N2, and N3 and a space under a lower surface of the first nanosheet N1. In the vertical direction (the Z direction), the thickness of each of the plurality of sub-gate portions 160S may be less than the thickness of the main gate portion 160M. Each of the plurality of gate lines 160 may extend to a space between the backside insulating pattern BBP and the first nanosheet N1. The nanosheet transistor TR may have a GAA structure in which the first to third nanosheets N1, N2, and N3 are completely surrounded by the gate line 160.

Each of the plurality of gate lines 160 may include a metal, a metal nitride, a metal carbide, or a combination thereof. The metal may be selected from Ti, W, Ru, Nb, Mo, Hf, Ni, Co, Pt, Yb, Tb, Dy, Er, and Pd. The metal nitride may be selected from TiN and TaN. The metal carbide may include TiAlC. However, a material constituting each of the plurality of gate lines 160 is not limited to the examples set forth above.

The gate dielectric film 152 may be arranged between the nanosheet stack NSS and the gate line 160. The gate dielectric film 152 may include a stack structure of an interface dielectric film and a high-k film. The interface dielectric film may include a low-k material film having a dielectric constant of about 9 or less, for example, a silicon oxide film, a silicon oxynitride film, or a combination thereof. In some embodiments, the interface dielectric film may be omitted. The high-k film may include a material having a dielectric constant that is greater than that of a silicon oxide film. For example, the high-k film may have a dielectric constant of about 10 to about 25. The high-k film may include, but is not limited to, hafnium oxide.

Either sidewall of each of the plurality of sub-gate portions 160S, which are included in each of the plurality of gate lines 160, may be apart from the source/drain region 130 with the gate dielectric film 152 therebetween. The gate dielectric film 152 may include portions arranged between the sub-gate portion 160S of the gate line 160 and each of the first to third nanosheets N1, N2, and N3, portions arranged between the sub-gate portion 160S of the gate line 160 and the source/drain region 130, and a portion arranged between the sub-gate portion 160S closest to the backside insulating pattern BBP, among the plurality of sub-gate portions 160S of the gate line 160, and the backside insulating pattern BBP. The backside insulating pattern BBP may include portions contacting the gate dielectric film 152.

In some embodiments, the frontside source/drain contact CA may include only a metal plug including a single metal. In some embodiments, the frontside source/drain contact CA may include a metal plug and a conductive barrier film surrounding the metal plug. A more detailed description of a constituent material of the frontside source/drain contact CA is the same as that of the backside via contact BCA described above.

In some embodiments, each of the frontside metal silicide film 172 and the backside metal silicide film 198 may include a metal silicide film including Ti, W, Ru, Nb, Mo, Hf, Ni, Co, Pt, Yb, Tb, Dy, Er, or PD. For example, each of the frontside metal silicide film 172 and the backside metal silicide film 198 may include, but is not limited to, titanium silicide.

As shown in FIG. 3, both sidewalls of the gate line 160 may be respectively covered by a plurality of main insulating spacers 118. Each of the plurality of main insulating spacers 118 may be arranged on the upper surface of the nanosheet stack NSS to cover a sidewall of the main gate portion 160M. Each of the plurality of main insulating spacers 118 may be apart from the gate line 160 with the gate dielectric film 152 therebetween.

As shown in FIG. 5, a plurality of side insulating spacers 119 may be arranged on the device isolation film 112. Each of the plurality of side insulating spacers 119 may cover a sidewall of the source/drain region 130. In some embodiments, each of the plurality of side insulating spacers 119 may be integrally connected to a main insulating spacer 118 adjacent thereto.

Each of the plurality of main insulating spacers 118 and the plurality of side insulating spacers 119 may include silicon nitride, silicon oxide, SiOC, SiOCN, SiCN, SiBN, SiON, SiBCN, SiOF, SiOCH, or a combination thereof. Each of the plurality of main insulating spacers 118 and the plurality of side insulating spacers 119 may include a single film including one material film selected from the materials listed above or may include a multi-film including a plurality of material films selected from the materials listed above.

As shown in FIGS. 3 and 4, the upper surface of each of the gate line 160, the gate dielectric film 152, and the main insulating spacer 118 may be covered by a capping insulating pattern 168. Each capping insulating pattern 168 may include a silicon nitride film.

The plurality of source/drain regions 130, the device isolation film 112, the plurality of main insulating spacers 118, and the plurality of side insulating spacers 119 may be covered by an insulating liner 142. The inter-gate dielectric 144 may be arranged on the insulating liner 142. The inter-gate dielectric 144 may be arranged between a pair of gate lines 160, which are adjacent to each other in the first horizontal direction (the X direction), and between a pair of source/drain regions 130 adjacent to each other. In some embodiments, the insulating liner 142 may include, but is not limited to, silicon nitride, SiCN, SiBN, SiON, SiOCN, SiBCN, or a combination thereof. The inter-gate dielectric 144 may include, but is not limited to, a silicon oxide film.

As shown in FIG. 2, the frontside source/drain contact CA may be arranged on the source/drain region 130 between a pair of gate lines 160 adjacent to each other from among the plurality of gate lines 160. One frontside source/drain contact CA may be connected to one source/drain region 130 or may be connected to two adjacent source/drain regions 130, but the inventive concept is not limited thereto. The frontside source/drain contact CA may be apart from the main gate portion 160M of the gate line 160, which is adjacent thereto, in the first horizontal direction (X direction) with the main insulating spacer 118 therebetween. A frontside insulating structure including the insulating liner 142 and the inter-gate dielectric 144 may surround the sidewall of the frontside source/drain contact CA.

As shown in FIGS. 3 to 5, respective upper surfaces of the frontside source/drain contact CA, a plurality of capping insulating patterns 168, the insulating liner 142, and the inter-gate dielectric 144 may be covered by an upper insulating structure 180. The upper insulating structure 180 may include an etch stop film 182 and an upper insulating film 184. The etch stop film 182 may include silicon carbide (SiC), SiN, SiCN, SiOC, AlN, AlON, AlO, AlOC, or a combination thereof. The upper insulating film 184 may include an oxide film, a nitride film, an ultra-low k (ULK) film having an ultra-low dielectric constant of about 2.2 to about 2.4, or a combination thereof. For example, the upper insulating film 184 may include, but is not limited to, a tetraethylorthosilicate (TEOS) film, a high-density plasma (HDP) oxide film, a boro-phospho-silicate glass (BPSG) film, a flowable chemical vapor deposition (FCVD) oxide film, a SiON film, a SiN film, a SiOC film, a SiCOH film, or a combination thereof.

A source/drain via contact VA may be arranged on the frontside source/drain contact CA. The source/drain via contact VA may pass through the upper insulating structure 180 to contact the frontside source/drain contact CA. The source/drain region 130 connected to the frontside source/drain contact CA, among the plurality of source/drain regions 130, may be configured to be electrically connected to the source/drain via contact VA via the frontside metal silicide film 172 and the frontside source/drain contact CA. Each of the plurality of source/drain via contacts VA may include, but is not limited to, molybdenum (Mo) or tungsten (W).

As shown in FIG. 4, a gate contact CB may be arranged on the gate line 160. The gate contact CB may be configured to pass through the upper insulating structure 180 and the capping insulating pattern 168 in the vertical direction (the Z direction) to be connected to the gate line 160. A lower surface of the gate contact CB may be in contact with the upper surface of the gate line 160. The gate contact CB may include a contact plug including molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof, but a constituent material of the contact plug is not limited to the examples set forth above. In some embodiments, the gate contact CB may further include a conductive barrier pattern surrounding a portion of the contact plug. The conductive barrier pattern of the gate contact CB may include a metal or a metal nitride. For example, the conductive barrier pattern may include, but is not limited to, Ti, Ta, W, TiN, TaN, WN, WCN, TiSiN, TaSiN, WSiN, or a combination thereof.

An upper surface of the upper insulating structure 180 may be covered by a frontside interlayer dielectric 186. A constituent material of the frontside interlayer dielectric 186 may be substantially the same as the constituent material of the upper insulating film 184 described above. A plurality of upper wiring layers M1 may be arranged through the frontside interlayer dielectric 186. Each of the plurality of upper wiring layers M1 may be connected to the source/drain via contact VA or the gate contact CB. Each of the plurality of upper wiring layers M1 may include, but is not limited to, molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof.

As described with reference to FIGS. 2 to 6, the integrated circuit device 100 includes a backside via contact BCA and a backside power rail MPR, which are configured to be connected to the source/drain region 130 and are integrally connected to each other, and a backside insulating pattern BBP, which overlaps the gate line 160 in the vertical direction (the Z direction) and is in contact with the sidewall of the backside power rail MPR in the first horizontal direction (the X direction). Because the second backside insulating portion B2, which contacts the backside power rail MPR, of the backside insulating pattern BBP has a shape having a gradually decreasing width in the first horizontal direction (the X direction) with an increasing distance from the gate line 160 in the vertical direction (the Z direction), unintended voids may be suppressed from being formed in each of the backside via contact BCA and the backside power rail MPR in a process of forming the backside via contact BCA and the backside power rail MPR, and a volume required to implement a low-resistance wiring line in the backside power rail MPR may be easily secured, thereby reducing the resistance of the backside via contact BCA and the backside power rail MPR. Therefore, according to the integrated circuit device 100, even when the integrated circuit device 100 includes a plurality of wiring structures at a relatively high concentration in an area reduced due to down-scaling, the reliability of the integrated circuit device 100 may be secured by improving electrical characteristics of the plurality of wiring structures including the backside via contact BCA and the backside power rail MPR, and the fabrication cost of the integrated circuit device 100 may be reduced by simplifying a fabrication process of the integrated circuit device 100.

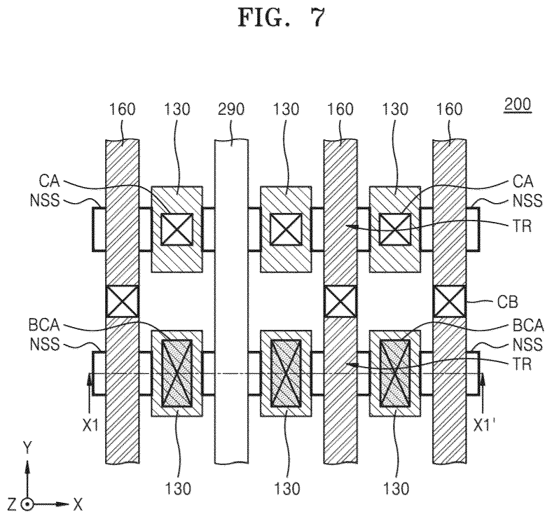

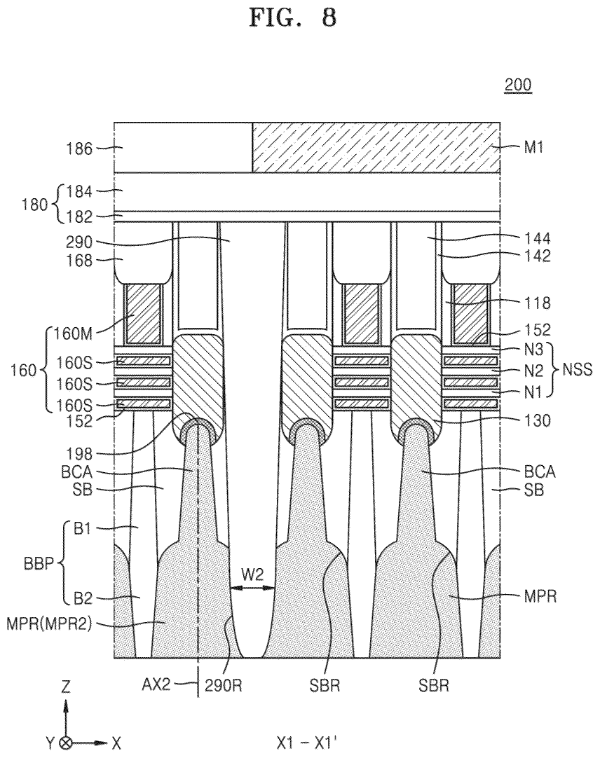

FIG. 7 is a planar layout diagram illustrating an integrated circuit device 200 according to some embodiments. FIG. 8 is a cross-sectional view of the integrated circuit device 200, taken along a line X1-X1′ of FIG. 7. In FIGS. 7 and 8, the same reference numerals as in FIGS. 2 to 6 respectively denote the same members, and here, repeated descriptions thereof are omitted. Components shown in FIGS. 7 and 8 may constitute a portion of the plurality of cells LC shown in FIG. 1.

Referring to FIGS. 7 and 8, the integrated circuit device 200 has substantially the same configuration as the integrated circuit device 100 described with reference to FIGS. 2 to 6. However, the integrated circuit device 200 includes a fin isolation insulating portion 290 between two adjacent gate lines 160 from among the plurality of gate lines 160.

The fin isolation insulating portion 290 may be located adjacent to the plurality of source/drain regions 130 to extend lengthwise in the second horizontal direction (the Y direction). The fin isolation insulating portion 290 may be arranged apart from, in the first horizontal direction (the X direction), the gate line 160 adjacent thereto with the plurality of source/drain regions 130 therebetween.

As shown in FIG. 8, the plurality of backside power rails MPR may include a backside power rail MPR2 contacting the fin isolation insulating portion 290. The fin isolation insulating portion 290 may include a fin isolation curved-surface 290R that is in contact with a sidewall of the backside power rail MPR2 in the first horizontal direction (the X direction). A portion, which contacts the backside power rail MPR2, of the fin isolation insulating portion 290 has an end width W2 defined in the first horizontal direction (the X direction) by the fin isolation curved-surface 290R. The end width W2 of the fin isolation insulating portion 290 may be less than the width of another portion, which does not contact the backside power rail MPR2, of the fin isolation insulating portion 290, for example, the width of a portion, which is closer to the source/drain region 130 than the fin isolation curved-surface 290R, of the fin isolation insulating portion 290.

In the integrated circuit device 200, the backside power rail MPR2 contacting the fin isolation insulating portion 290, among the plurality of backside power rails MPR, may have a gradually increasing width in the first horizontal direction (the X direction) with an increasing distance from the source/drain region 130 corresponding to the backside power rail MPR2 in the vertical direction (the Z direction). Both sidewalls of the backside power rail MPR2 contacting the fin isolation insulating portion 290, among the plurality of backside power rails MPR, may have asymmetric shapes to each other. For example, a cross-sectional shape of the backside power rail MPR2 in the first horizontal direction (the X direction) may include two side portions asymmetric to each other about an extension line AX2 of a central axis, in the vertical direction (the Z direction), of the backside via contact BCA integrally connected to the backside power rail MPR2.

The fin isolation insulating portion 290 may have a line-shaped planar structure extending together with and parallel to the plurality of gate lines 160 in the second horizontal direction (the Y direction). In the first horizontal direction (the X direction), a distance between the fin isolation insulating portion 290 and one gate line 160 selected from a pair of gate lines 160, which are adjacent to each other and on both sides of the fin isolation insulating portion 290, may be equal or similar to a distance between the fin isolation insulating portion 290 and the other gate line 160 selected from the pair of gate lines 160. One source/drain region 130 may be arranged between the fin isolation insulating portion 290 and one gate line 160 adjacent to the fin isolation insulating portion 290.

The fin isolation insulating portion 290 may include a portion facing, in the first horizontal direction, each of the plurality of gate lines 160, the plurality of gate dielectric films 152, the plurality of insulating spacers 118, and the capping insulating pattern 168. The upper surface of the capping insulating pattern 168 may be coplanar with the upper surface of the fin isolation insulating portion 290. The fin isolation insulating portion 290 may include a portion that is apart from the backside via contact BCA in the first horizontal direction (the X direction). In the first horizontal direction (the X direction), the semiconductor block SB may be arranged between the fin isolation insulating portion 290 and the backside via contact BCA. The fin isolation insulating portion 290 may include a single-film structure including a single insulating material layer, or a multi-film structure including a plurality of insulating material layers. The fin isolation insulating portion 290 may include, but is not limited to, a silicon nitride film, a silicon oxide film, a SiON film, a SiOCN film, a SiCN film, or a combination thereof.

Similar to the integrated circuit device 100 described with reference to FIGS. 2 to 6, the integrated circuit device 200 described with reference to FIGS. 7 and 8 includes a backside insulating pattern BBP, which is in contact with the sidewall of the backside power rail MPR in the first horizontal direction (the X direction), and also includes a fin isolation insulating portion 290, which is in contact with the sidewall of the backside power rail MPR2 in the first horizontal direction (the X direction). The second backside insulating portion B2, which contacts the backside power rail MPR, of the backside insulating pattern BBP may have a shape having a gradually decreasing width in the first horizontal direction (the X direction) with an increasing distance from the gate line 160 in the vertical direction (the Z direction), and an end width W2 of a portion, which contacts the backside power rail MPR2, of the fin isolation insulating portion 290 may be less than the width of another portion, which does not contact the backside power rail MPR2, of the fin isolation insulating portion 290. Therefore, unintended voids may be suppressed from being formed in each of the backside via contact BCA and the backside power rail MPR in a process of forming the backside via contact BCA and the backside power rail MPR, and a volume required to implement a low-resistance wiring line in the backside power rail MPR may be easily secured, thereby reducing the resistance of the backside via contact BCA and the backside power rail MPR. Therefore, according to the integrated circuit device 200, even when the integrated circuit device 200 includes a plurality of wiring structures at a relatively high concentration in an area reduced due to down-scaling, the reliability of the integrated circuit device 200 may be secured by improving electrical characteristics of the plurality of wiring structures including the backside via contact BCA and the backside power rail MPR, and the fabrication cost of the integrated circuit device 200 may be reduced by simplifying a fabrication process of the integrated circuit device 200.

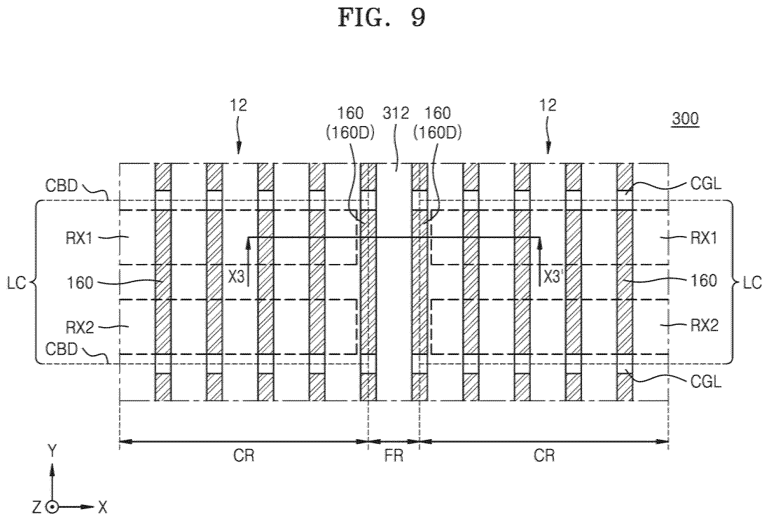

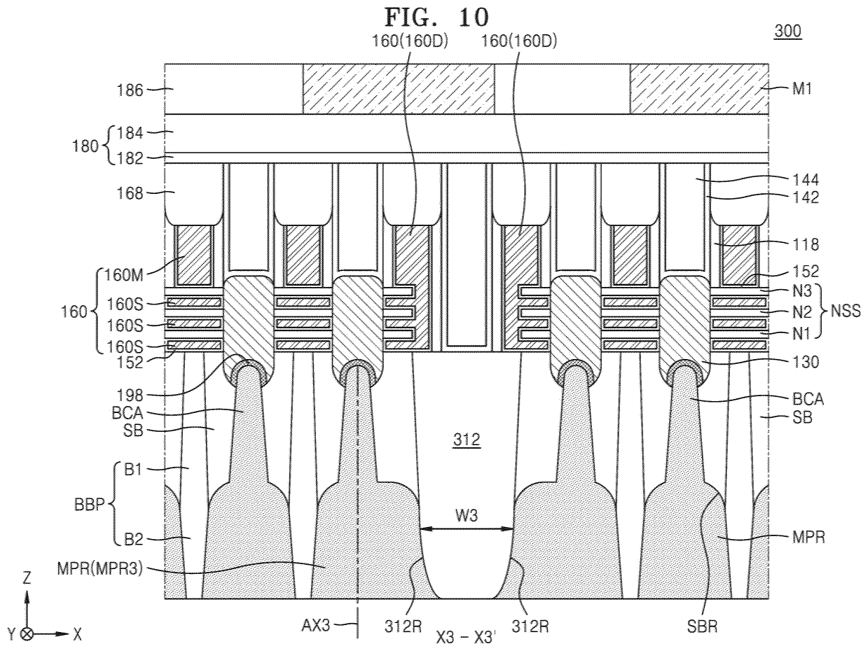

FIG. 9 is a planar layout diagram illustrating an integrated circuit device 300 according to some embodiments. FIG. 10 is a cross-sectional view of the integrated circuit device 300, taken along a line X3-X3′ of FIG. 9. In FIGS. 9 and 10, the same reference numerals as in FIGS. 2 to 6 respectively denote the same members, and here, repeated descriptions thereof are omitted. Components shown in FIGS. 9 and 10 may constitute a portion of the plurality of cells LC shown in FIG. 1.

Referring to FIGS. 9 and 10, the integrated circuit device 300 has substantially the same configuration as the integrated circuit device 100 described with reference to FIGS. 2 to 6. More specifically, the integrated circuit device 300 may include a plurality of cell areas CR that are apart from each other in the first horizontal direction (the X direction). Each of the plurality of cell areas CR may include a plurality of cells LC arranged in a line in the second horizontal direction (the Y direction) intersecting with the first horizontal direction (the X direction). An inter-cell isolation area FR may be arranged between two adjacent cell areas CR in the first horizontal direction (the X direction) from among the plurality of cell areas CR and may extend lengthwise in the second horizontal direction (the Y direction).

Each of the plurality of cell areas CR may include a cell block 12 including a plurality of cells LC. The cell block 12 may include a plurality of cells LC including circuit patterns for constituting various circuits. The plurality of cells LC may be arranged in a matrix in the first horizontal direction (the X direction) and the second horizontal direction (the Y direction) in the cell block 12.

In each of the plurality of cells LC in the plurality of cell areas CR, the plurality of gate lines 160 may extend lengthwise in the second horizontal direction (the Y direction). A gate line 160 extending along the boundary between the inter-cell isolation area FR and a cell area CR, among the plurality of gate lines 160, may be a dummy gate line 160D not operating as a normal gate, and a gate line 160 arranged apart from, in the first horizontal direction (the X direction), the boundary between the inter-cell isolation area FR and the cell area CR, among the plurality of gate lines 160, may be a gate line 160 configured to operate as a normal gate.

In the integrated circuit device 300, each of the plurality of cells LC may include a first device area RX1 and a second device area RX2. Each of the first device area RX1 and the second device area RX2 may include the components described with reference to FIGS. 2 to 6. In some embodiments, one of the first device area RX1 and the second device area RX2 may be an NMOS transistor area, and the other may be a PMOS transistor area.

As shown in FIG. 10, the dummy gate line 160D may be arranged adjacent to the source/drain region 130 in the first horizontal direction (the X direction). In the plurality of gate lines 160, the dummy gate line 160D may be arranged apart from, in the first horizontal direction (the X direction), the gate line 160 configured to operate as a normal gate with the source/drain region 130 therebetween.

The integrated circuit device 300 may include a field device isolation film 312 arranged in the inter-cell isolation area FR. As shown in FIG. 10, the field device isolation film 312 may be arranged to overlap at least one dummy gate line 160D in the vertical direction (the Z direction). The field device isolation film 312 may include an oxide film, a nitride film, or a combination thereof.

The plurality of backside power rails MPR may include a backside power rail MPR3 contacting the field device isolation film 312. The field device isolation film 312 may include a field device isolation curved-surface 312R that is in contact with a sidewall of the backside power rail MPR3 in the first horizontal direction (the X direction). A portion, which contacts the backside power rail MPR3, of the field device isolation film 312 has an end width W3 defined in the first horizontal direction (the X direction) by the field device isolation curved-surface 312R. The end width W3 of the field device isolation film 312 may be less than the width of another portion, which does not contact the backside power rail MPR3, of the field device isolation film 312, for example, the width of a portion, which is closer to the dummy gate line 160D than the field device isolation curved-surface 312R, of the field device isolation film 312.

The field device isolation film 312 may include a portion that is apart from the backside via contact BCA in the first horizontal direction (the X direction). In the first horizontal direction (the X direction), the semiconductor block SB may be arranged between the field device isolation film 312 and the backside via contact BCA.

In the integrated circuit device 300, the backside power rail MPR3 contacting the field device isolation film 312, among the plurality of backside power rails MPR, may have a gradually increasing width in the first horizontal direction (the X direction) with an increasing distance from the source/drain region 130 corresponding to the backside power rail MPR3 in the vertical direction (the Z direction). Both sidewalls of the backside power rail MPR3 contacting the field device isolation film 312, among the plurality of backside power rails MPR, may have asymmetric shapes to each other. For example, both portions of a cross-sectional shape of the backside power rail MPR3 in the first horizontal direction (the X direction) may be asymmetric to each other about an extension line AX3 of a central axis, in the vertical direction (the Z direction), of the backside via contact BCA integrally connected to the backside power rail MPR3.

In some embodiments, the plurality of source/drain regions 130 in the first device area RX1 may be different in shapes and sizes from the plurality of source/drain regions 130 in the second device area RX2. The shape of each of the plurality of source/drain regions 130 is not limited to the example shown in FIG. 10, and the plurality of source/drain regions 130 having various shapes and sizes may be formed in the first device area RX1 and the second device area RX2.

As shown in FIG. 9, in each of the plurality of cells LC, a plurality of gate cut insulating patterns CGL may be arranged in the cell boundary CBD extending in the first horizontal direction (the X direction). The plurality of gate cut insulating patterns CGL may be respectively arranged in extension lines of the plurality of gate lines 160. In some embodiments, each of the plurality of gate cut insulating patterns CGL may include, but is not limited to, a silicon nitride film. Although FIG. 9 illustrates an example of a configuration in which the plurality of gate cut insulating patterns CGL extend in the second horizontal direction (the Y direction) across the cell boundary CBD of each of a pair of cells LC that are adjacent to each other in the second horizontal direction (the Y direction) in the cell block 12, the position and the planar shape of each of the plurality of gate cut insulating patterns CGL are not limited to the example shown in FIG. 9.

Similar to the integrated circuit device 100 described with reference to FIGS. 2 to 6, the integrated circuit device 300 described with reference to FIGS. 9 and 10 includes a backside insulating pattern BBP, which is in contact with the sidewall of the backside power rail MPR in the first horizontal direction (the X direction), and also includes a field device isolation film 312, which is in contact with the sidewall of the backside power rail MPR3 in the first horizontal direction (the X direction). The second backside insulating portion B2, which contacts the backside power rail MPR, of the backside insulating pattern BBP may have a shape having a gradually decreasing width in the first horizontal direction (the X direction) with an increasing distance from the gate line 160 in the vertical direction (the Z direction), and an end width W3 of a portion, which contacts the backside power rail MPR3, of the field device isolation film 312 may be less than the width of another portion, which does not contact the backside power rail MPR3, of the field device isolation film 312. Therefore, unintended voids may be suppressed from being formed in each of the backside via contact BCA and the backside power rail MPR in a process of forming the backside via contact BCA and the backside power rail MPR, and a volume required to implement a low-resistance wiring line in the backside power rail MPR may be easily secured, thereby reducing the resistance of the backside via contact BCA and the backside power rail MPR. Therefore, according to the integrated circuit device 300, even when the integrated circuit device 300 includes a plurality of wiring structures at a relatively high concentration in an area reduced due to down-scaling, the reliability of the integrated circuit device 300 may be secured by improving electrical characteristics of the plurality of wiring structures including the backside via contact BCA and the backside power rail MPR, and the fabrication cost of the integrated circuit device 300 may be reduced by simplifying a fabrication process of the integrated circuit device 300.

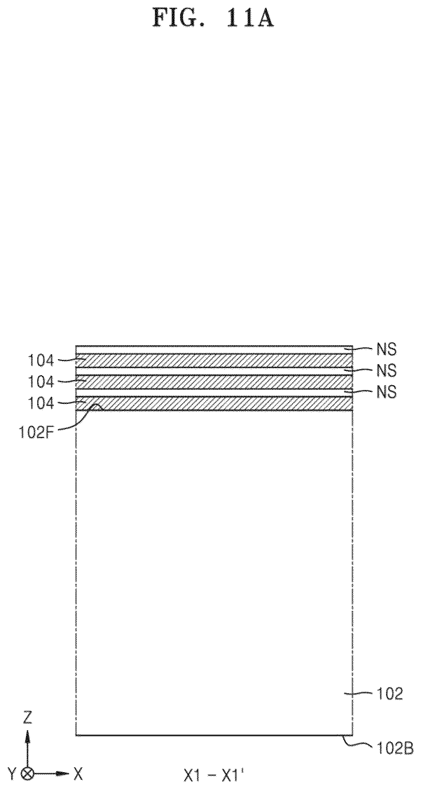

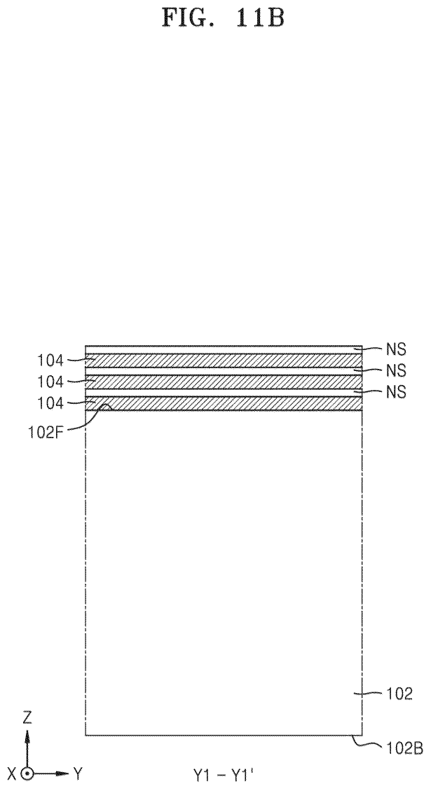

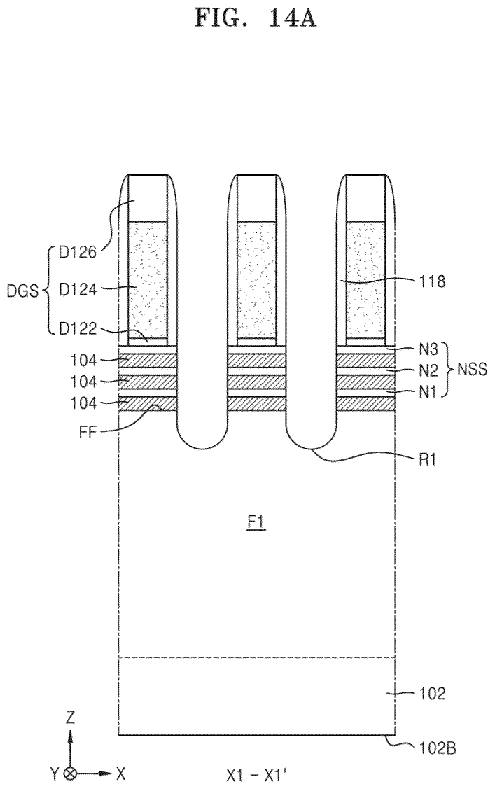

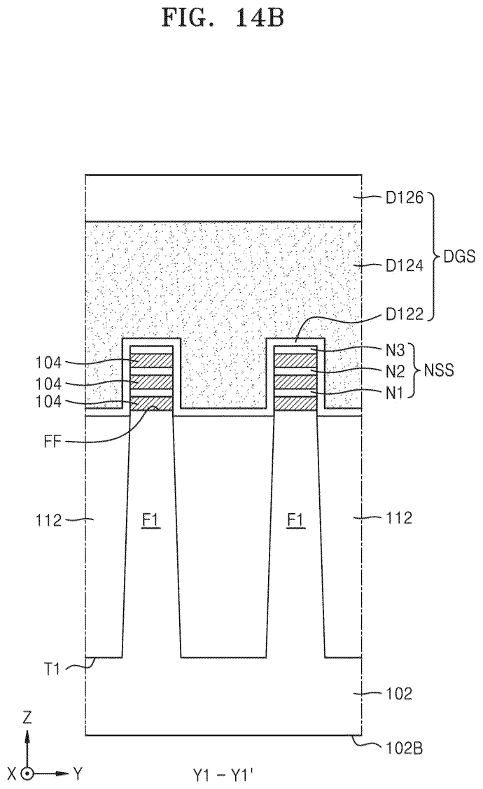

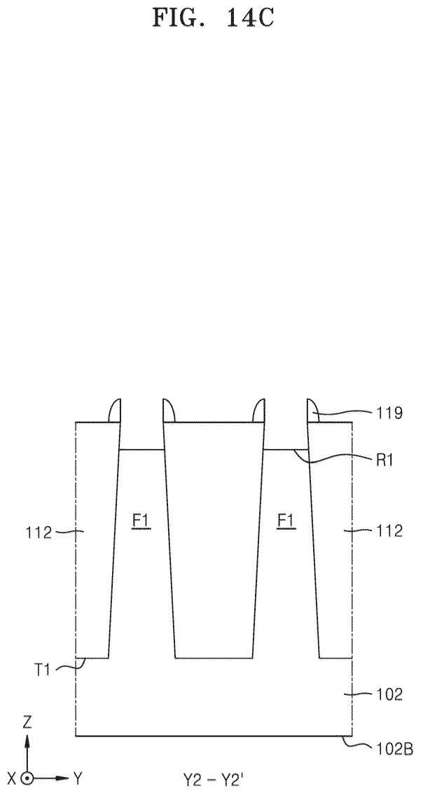

FIGS. 11A to 22C are cross-sectional views respectively illustrating a sequence of processes of a method of fabricating an integrated circuit device, according to embodiments. More specifically, FIGS. 11A, 12A, 13A, 14A, 15A, 16A, 17A, 18A, 19A, 20A, 21A, and 22A are cross-sectional views respectively illustrating cross-sectional structures of a region corresponding to the cross-section taken along the line X1-X1′ of FIG. 2, according to the sequence of processes. FIGS. 11B, 12B, 13B, 14B, 15B, 16B, 17B, 18B, 19B, 20B, 21B, and 22B are cross-sectional views respectively illustrating cross-sectional structures of a region corresponding to the cross-section taken along the line Y1-Y1′ of FIG. 2, according to the sequence of processes. FIGS. 14C, 15C, 19C, 20C, 21C, and 22C are cross-sectional views respectively illustrating cross-sectional structures of a region corresponding to the cross-section taken along the line Y2-Y2′ of FIG. 2, according to the sequence of processes. An example of a method of fabricating the integrated circuit device 100 described with reference to FIGS. 2 to 6 is described with reference to FIGS. 11A to 22C. In FIGS. 11A to 22C, the same reference numerals as in FIGS. 2 to 6 respectively denote the same members, and here, repeated descriptions thereof are omitted.

Referring to FIGS. 11A and 11B, a substrate 102 having a frontside surface 102F and a backside surface 102B, which are opposite to each other, may be prepared, and a stack structure, in which a plurality of sacrificial semiconductor layers 104 and a plurality of nanosheet semiconductor layers NS are alternately stacked one-by-one, may be formed on the frontside surface 102F of the substrate 102.

In the stack structure, each of the plurality of sacrificial semiconductor layers 104 and each of the plurality of nanosheet semiconductor layers NS may include semiconductor materials having different etch selectivities, respectively. In some embodiments, each of the plurality of nanosheet semiconductor layers NS may include a Si layer, and each of the plurality of sacrificial semiconductor layers 104 may include a SiGe layer. The SiGe layer constituting each of the plurality of sacrificial semiconductor layers 104 may have a constant Ge content selected from a range of about 5 at % to about 50 at %, for example, about 10 at % to about 40 at %. In some embodiments, each of the plurality of sacrificial semiconductor layers 104 may include a SiGe layer, and the respective Ge contents in the plurality of sacrificial semiconductor layers 104 may be equal to each other.

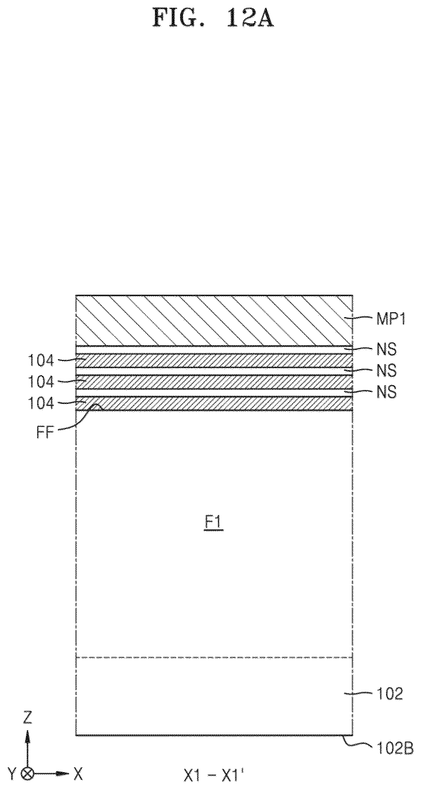

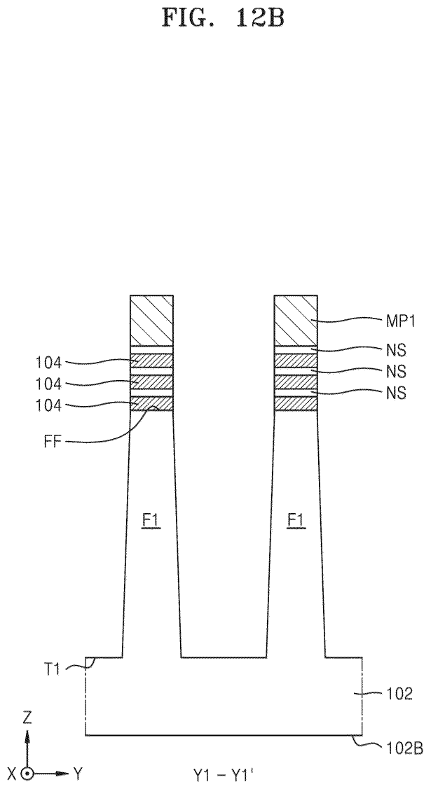

Referring to FIGS. 12A and 12B, a mask pattern MP1 having openings, which expose the upper surface of the stack structure, may be formed on the resulting product of FIGS. 11A and 11B. The mask pattern MP1 may include a stack structure of a silicon oxide film pattern and a silicon nitride film pattern. The mask pattern MP1 may include portions extending parallel to each other in the first horizontal direction (the X direction) over the substrate 102.

The term “exposed,” may be used to describe relationships between elements and/or certain intermediate processes in fabricating a completed semiconductor device, but may not necessarily require exposure of the particular region, layer, structure or other element in the context of the completed device.

Each of the plurality of sacrificial semiconductor layers 104, the plurality of nanosheet semiconductor layers NS, and the substrate 102 may be partially etched by using the mask pattern MP1 as an etch mask, thereby forming a plurality of fin-type active regions F1 in the substrate 102. A plurality of trench regions T1 may be defined on the substrate 102 by the plurality of fin-type active regions F1. A portion of each of the plurality of sacrificial semiconductor layers 104 and the plurality of nanosheet semiconductor layers NS may remain on or over a fin top surface FF of each of the plurality of fin-type active regions F1.

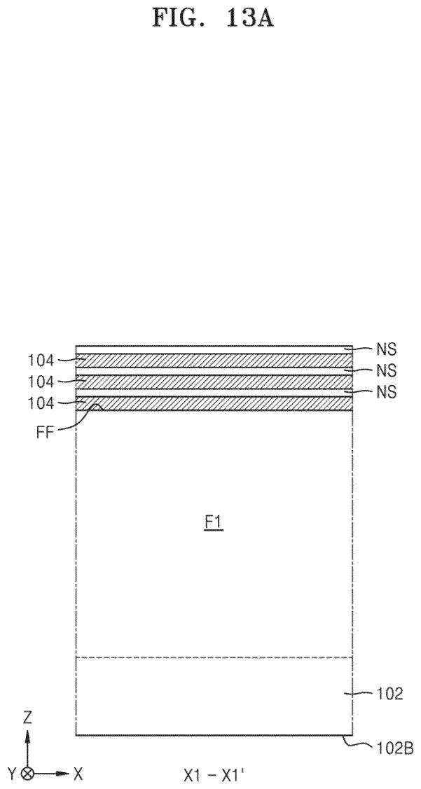

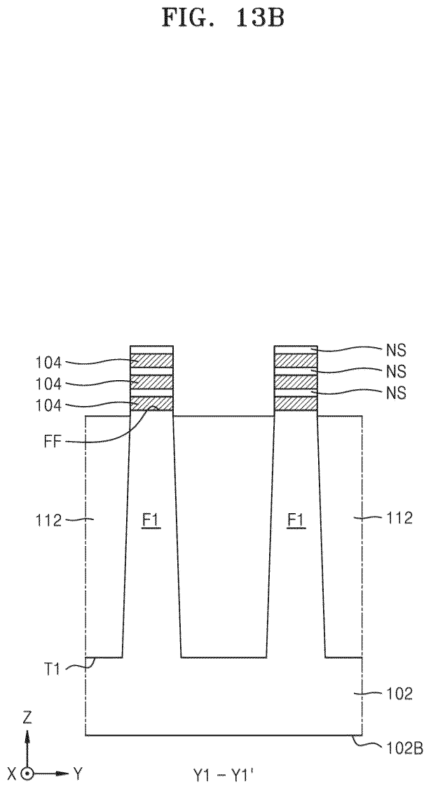

Referring to FIGS. 13A and 13B, the device isolation film 112 may be formed on the resulting product of FIGS. 12A and 12B. The device isolation film 112 may be formed to fill the plurality of trench regions T1 and to cover sidewalls of each of the plurality of fin-type active regions F1.

To form the device isolation film 112, an insulating film may be formed on the resulting product of FIGS. 12A and 12B to have a thickness enough to fill the plurality of trench regions T1, and the upper surface of the mask pattern MP1 may be exposed by planarizing the obtained resulting product. Next, the mask pattern MP1 that is exposed may be removed, and then, a recess process for removing a portion of the insulating film may be performed, thereby forming the device isolation film 112, which includes the remaining portion of the insulating film. After the device isolation film 112 is formed, the stack structure including the plurality of sacrificial semiconductor layers 104 and the plurality of nanosheet semiconductor layers NS, which remain on or over the substrate 102, may protrude upward from the upper surface of the device isolation film 112, and the upper surface of the uppermost nanosheet semiconductor layer NS from among the plurality of nanosheet semiconductor layers NS may be exposed.

Referring to FIGS. 14A, 14B, and 14C, a plurality of dummy gate structures DGS may be formed on the resulting product of FIGS. 13A and 13B. Each of the plurality of dummy gate structures DGS may be formed to extend lengthwise in the second horizontal direction (the Y direction). Each of the plurality of dummy gate structures DGS may include a dummy oxide film D122, a dummy gate layer D124, and a capping layer D126, which are stacked in the stated order on the stack structure including the plurality of sacrificial semiconductor layers 104 and the plurality of nanosheet semiconductor layers NS. In some embodiments, the dummy gate layer D124 may include polysilicon and the capping layer D126 may include a silicon nitride film.

As shown in FIG. 14A, a plurality of insulating spacers 118 may be formed to respectively cover both sidewalls of each of the plurality of dummy gate structures DGS, and a portion of each of the plurality of sacrificial semiconductor layers 104 and the plurality of nanosheet semiconductor layers NS and a portion of the fin-type active region F1 may be etched by using the plurality of dummy gate structures DGS and the plurality of insulating spacers 118 as an etch mask, thereby dividing the plurality of nanosheet semiconductor layers NS into the plurality of nanosheet stacks NSS, which each include the first to third nanosheets N1, N2, and N3, and forming a plurality of recesses R1 in an upper portion of the fin-type active region F1. The width of each of the first to third nanosheets N1, N2, and N3 in the first horizontal direction (the X direction) may be defined by the plurality of recesses R1.

To form the plurality of recesses R1, the etching may be performed by dry etching, wet etching, or a combination thereof. During the formation of the plurality of insulating spacers 118 and the plurality of recesses R1, the plurality of side insulating spacers 119 may be formed as shown in FIG. 14C, the plurality of side insulating spacers 119 being arranged on the device isolation film 112 on both sides of each fin-type active region F1 in the second horizontal direction (the Y direction) to be respectively adjacent to the plurality of recesses R1.

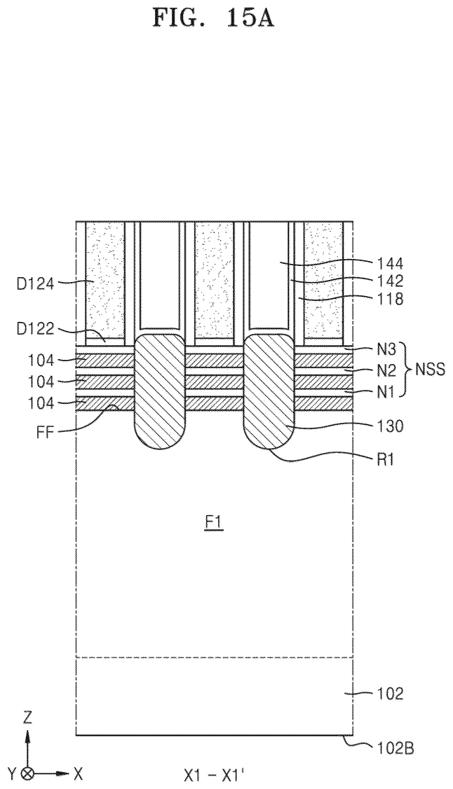

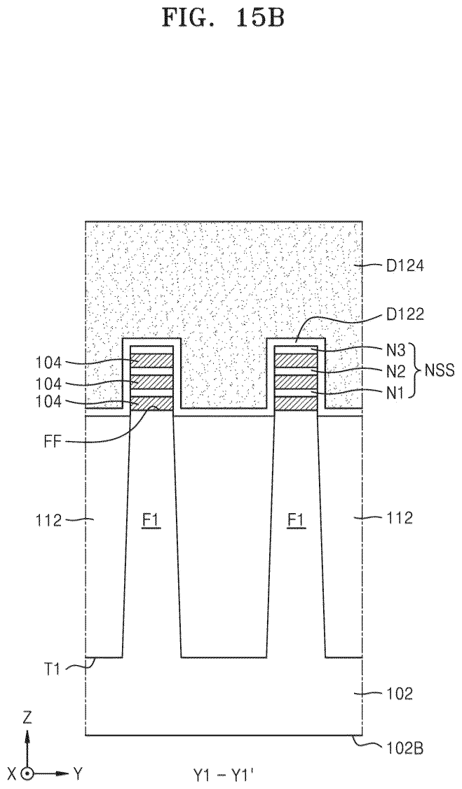

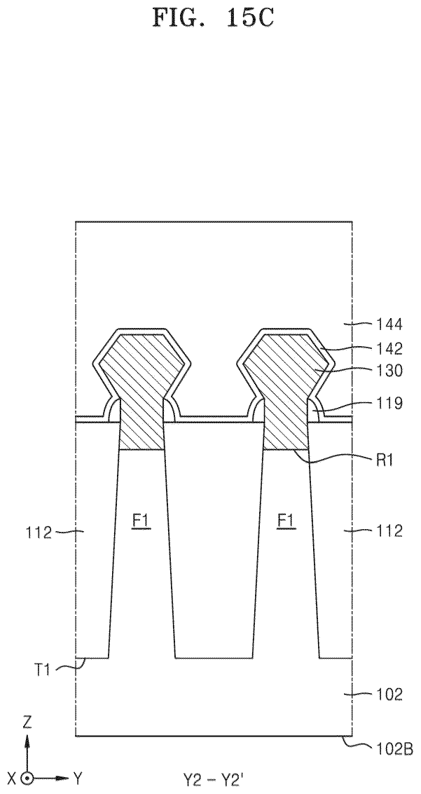

Referring to FIGS. 15A, 15B, and 15C, in the resulting product of FIGS. 14A, 14B, and 14C, the plurality of source/drain regions 130 may be formed by epitaxially growing a semiconductor material on a surface of the fin-type active region F1, which is exposed at a lower surface of each recess R1 in a bottom-up manner.

In some embodiments, to form the plurality of source/drain regions 130, a low-pressure chemical vapor deposition (LPCVD) process, a selective epitaxial growth (SEG) process, or a cyclic deposition and etching (CDE) process may be performed by using source materials including an elemental semiconductor precursor. The elemental semiconductor precursor may include an element, such as Si or Ge.

In some embodiments, the plurality of source/drain regions 130 may each include a SiGe layer doped with boron (B). In this case, to form the plurality of source/drain regions 130, the substrate 102 may be in-situ doped with boron (B) ions while supplying a Si source and a Ge source onto the substrate 102. The Si source may include, but is not limited to, silane (SiH₄), disilane (Si₂H₆), trisilane (Si₃H₈), dichlorosilane (SiH₂Cl₂), or the like. The Ge source may include, but is not limited to, germane (GeH₄), digermane (Ge₂H₆), trigermane (Ge₃H₈), tetragermane (Ge₄H₁₀), dichlorogermane (Ge₂H₂Cl₂), or the like. A boron (B) ion source may include, but is not limited to, diborane (B₂H₆), triborane, tetraborane, pentaborane, or the like.

In some embodiments, the plurality of source/drain regions 130 may each include a Si layer doped with phosphorus (P). In this case, to form the plurality of source/drain regions 130, the substrate 102 may be in-situ doped with phosphorus (P) ions while supplying a Si source onto the substrate 102. The Si source may be selected from the materials set forth above as examples. A phosphorus (P) ion source may include, but is not limited to, phosphine (PH₃) gas.

The insulating liner 142 may be formed to cover the resulting product in which the plurality of source/drain regions 130 are formed, followed by forming the inter-gate dielectric 144 on the insulating liner 142, and then, a portion of each of the insulating liner 142 and the inter-gate dielectric 144 may be etched, thereby exposing the upper surfaces of the plurality of capping layers D126 (see FIGS. 14A and 14B). Next, the dummy gate layer D124 may be exposed by removing the plurality of capping layers D126, and the insulating liner 142 and the inter-gate dielectric 144 may be partially removed such that the upper surface of the inter-gate dielectric 144 and the upper surface of the dummy gate layer D124 are at an approximately equal level.

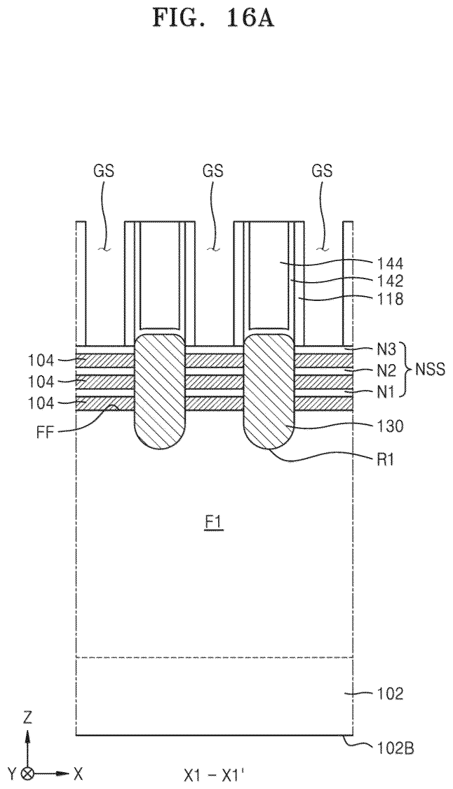

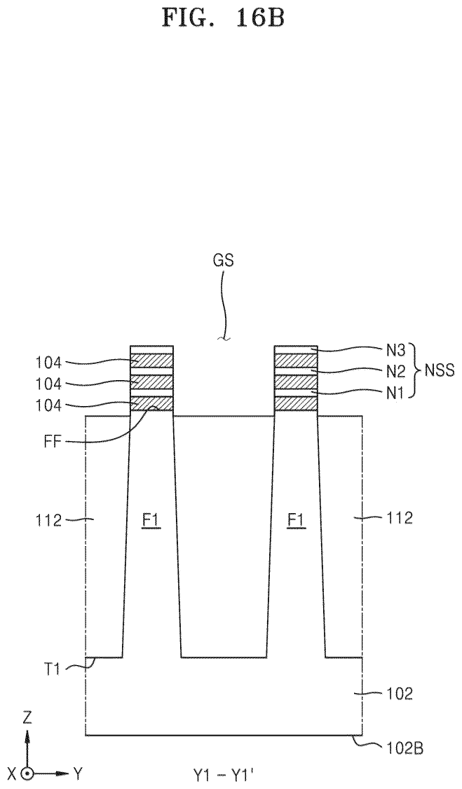

Referring to FIGS. 16A and 16B, the dummy gate layer D124 and the dummy oxide film D122 may be removed from the resulting product of FIGS. 15A, 15B, and 15C, thereby preparing a gate space GS.

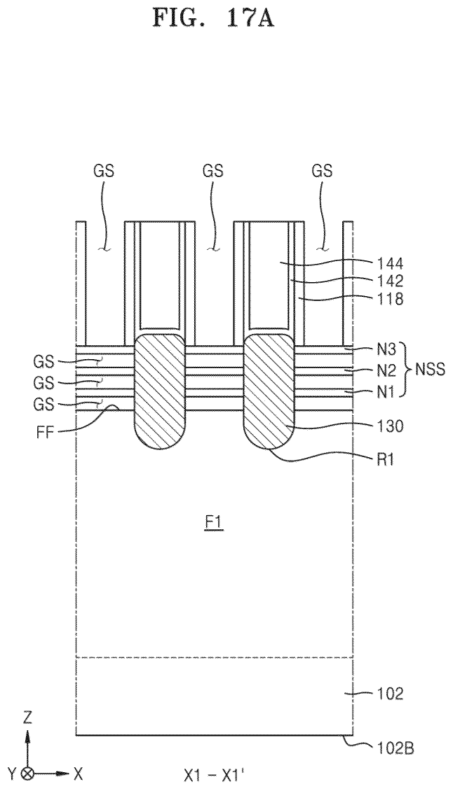

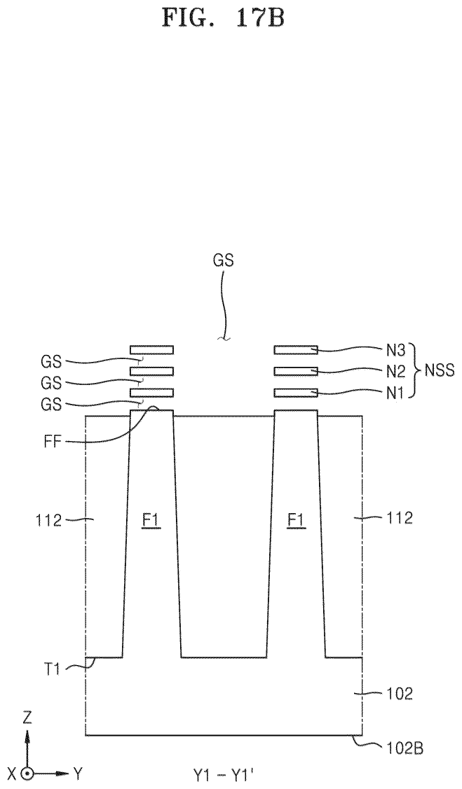

Referring to FIGS. 17A and 17B, in the resulting product of FIGS. 16A and 16B, the plurality of sacrificial semiconductor layers 104 remaining over the substrate 102 may be selectively removed from the resulting product of FIGS. 16A and 16B through the gate space GS, thereby expanding the gate space GS to a space between each of the first to third nanosheets N1, N2, and N3 and to a space between the fin top surface FF of the fin-type active region F1 and the first nanosheet N1.

In some embodiments, to selectively remove the plurality of sacrificial semiconductor layers 104, a difference in etch selectivity between each of the plurality of sacrificial semiconductor layers 104 and each of the fin-type active region F1 and the first to third nanosheets N1, N2, and N3 may be used. To selectively remove the plurality of sacrificial semiconductor layers 104, a liquid-phase or gas-phase etchant may be used. In some embodiments, to selectively remove the plurality of sacrificial semiconductor layers 104, a CH₃COOH-based etching solution, for example, an etching solution including a mixture of CH₃COOH, HNO₃, and HF, or an etching solution including a mixture of CH₃COOH, H₂O₂, and HF, may be used, but the inventive concept is not limited thereto.

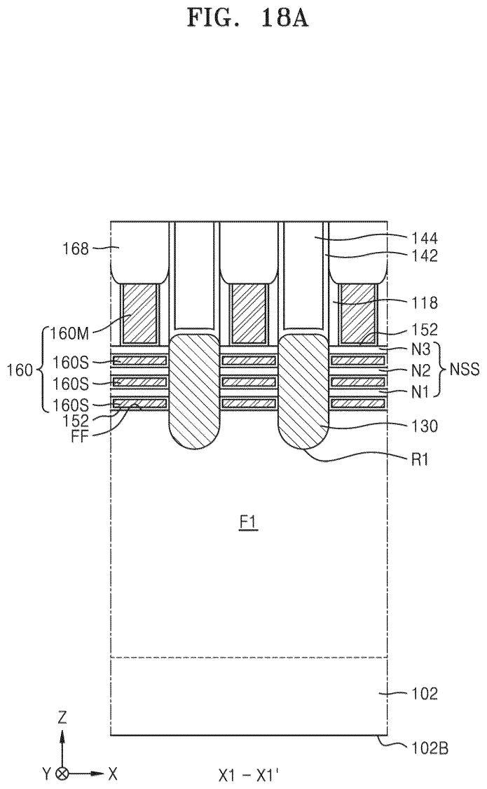

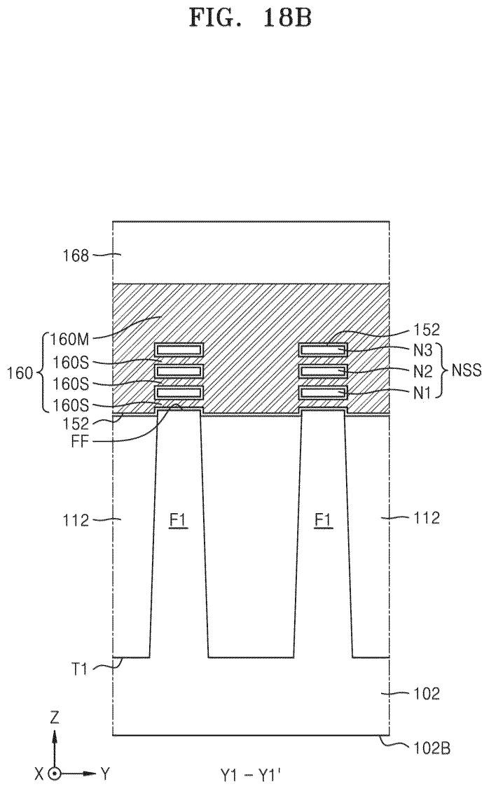

Referring to FIGS. 18A and 18B, in the resulting product of FIGS. 17A and 17B, the gate dielectric film 152 may be formed to cover respective exposed surfaces of the fin-type active region F1 and the first to third nanosheets N1, N2, and N3. To form the gate dielectric film 152, an atomic layer deposition (ALD) process may be used.

Next, the gate line 160 may be formed on the gate dielectric film 152 to fill the gate space GS (see FIGS. 17A and 17B). Next, each of the gate line 160, the gate dielectric film 152, and the insulating spacer 118 may be partially removed from the upper surface thereof to reduce the height thereof, and the plurality of capping insulating patterns 168 may each be formed to cover the upper surface of each of the gate line 160, the gate dielectric film 152, and the insulating spacer 118.

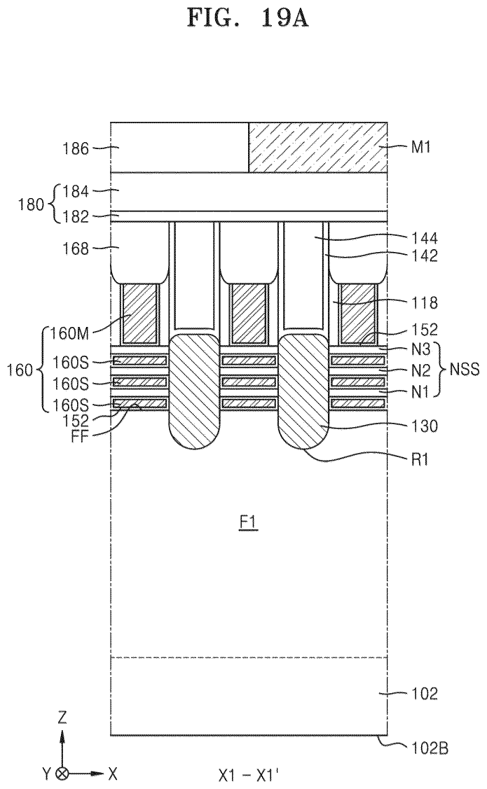

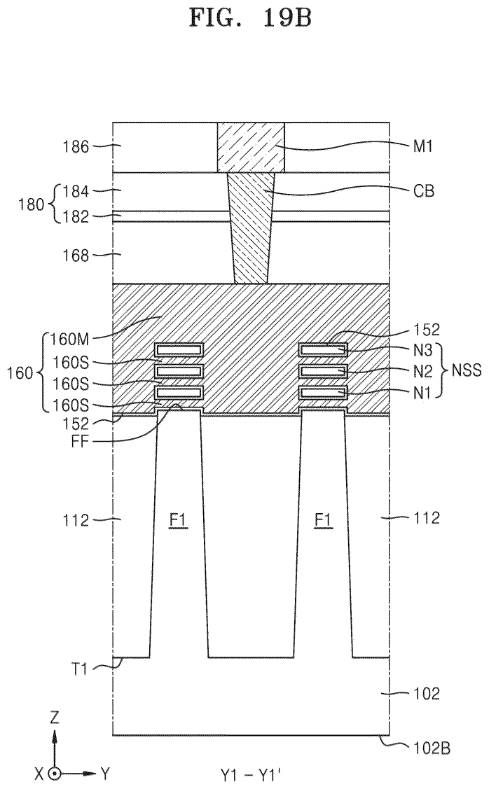

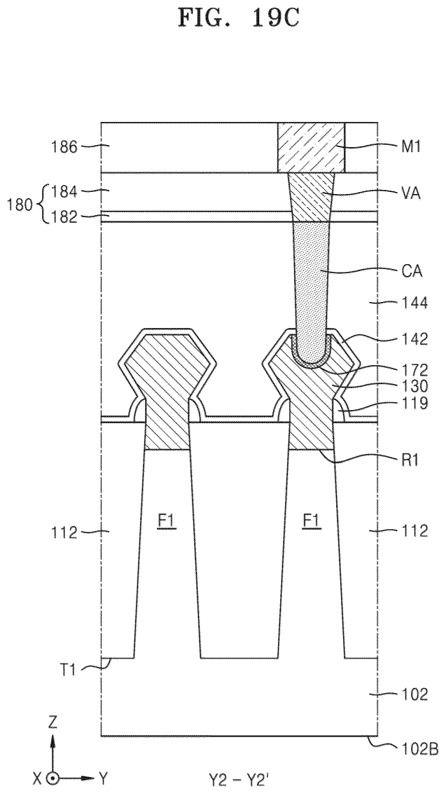

Referring to FIGS. 19A, 19B, and 19C, in the resulting product having undergone the processes described with reference to FIGS. 18A and 18B, a source/drain contact hole may be formed between two adjacent gate lines 160 from among the plurality of gate lines 160 to expose the source/drain region 130, followed by forming the frontside metal silicide film 172 on the surface of the source/drain region 130 through the source/drain contact hole, and then, the frontside source/drain contact CA may be formed on the frontside metal silicide film 172 to fill the source/drain contact hole.

Next, the etch stop film 182 and the upper insulating film 184 may be formed in the stated order to cover the upper surface of each of the frontside source/drain contact CA, the plurality of capping insulating patterns 168, and the inter-gate dielectric 144, thereby forming the upper insulating structure 180. Next, the source/drain via contact VA, which passes through the upper insulating structure 180 in the vertical direction (the Z direction) to be connected to the frontside source/drain contact CA, and the gate contact CB, which passes through the upper insulating structure 180 and the capping insulating pattern 168 in the vertical direction (the Z direction) to be connected to the gate line 160, may be formed. The source/drain via contact VA and the gate contact CB may be simultaneously formed or may be respectively formed by separate processes. Next, the frontside interlayer dielectric 186, which covers the upper insulating structure 180, and the plurality of upper wiring layers M1, which pass through the frontside interlayer dielectric 186, may be formed. The plurality of upper wiring layers M1 may include an upper wiring layer M1 connected to the source/drain via contact VA and an upper wiring layer M1 connected to the gate contact CB. Next, a frontside wiring structure (not shown) may be formed on the frontside interlayer dielectric 186 and the plurality of upper wiring layers M1.

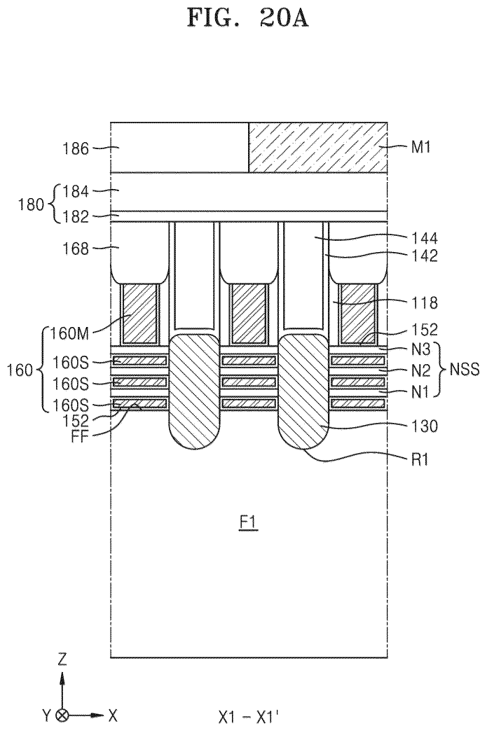

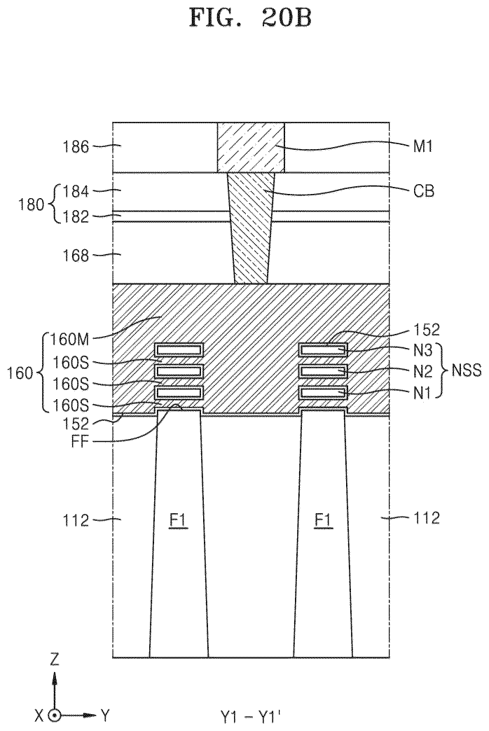

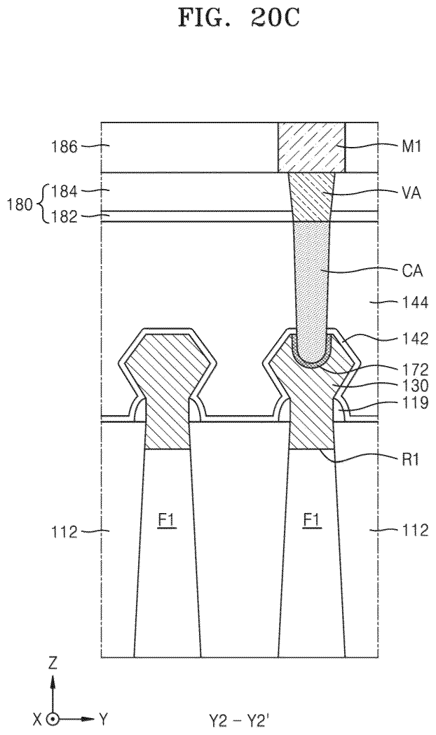

Referring to FIGS. 20A, 20B, and 20C, in the resulting product of FIGS. 19A, 19B, and 19C, the plurality of fin-type active regions F1 and the device isolation film 112 may be exposed by removing the substrate 102 from the backside surface 102B of the substrate 102. In some embodiments, a process of removing the substrate 102 may include at least one process selected from a mechanical grinding process, a chemical mechanical polishing (CMP) process, a wet etching process, and a combination thereof may be used.

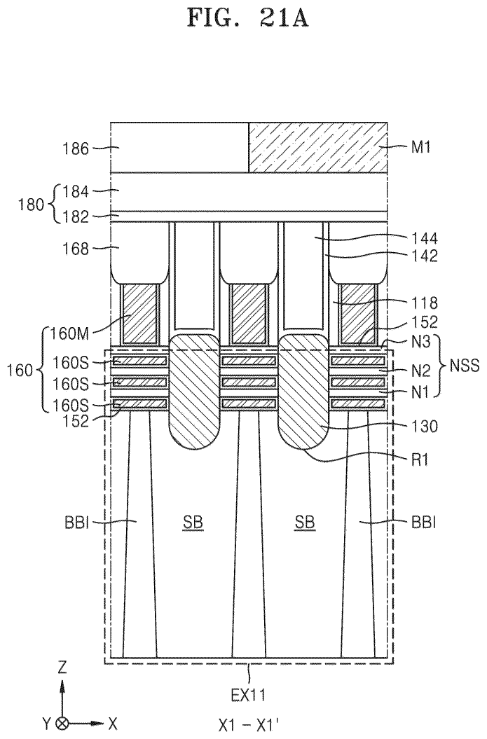

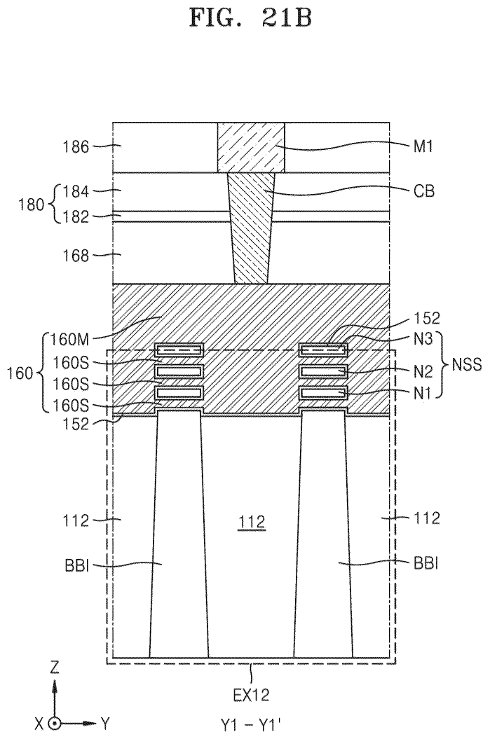

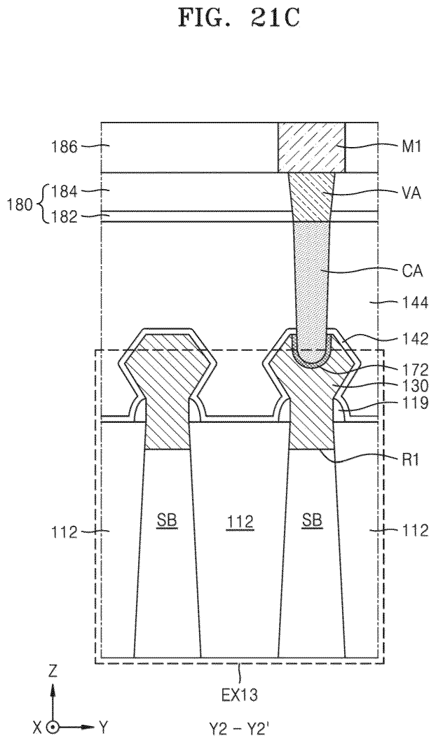

Referring to FIGS. 21A, 21B, and 21C, in the resulting product of FIGS. 20A, 20B, and 20C, a plurality of vertical holes may be formed to expose the gate dielectric film 152 by partially etching each of the plurality of fin-type active regions F1 from a backside surface at which the plurality of fin-type active regions F1 and the device isolation film 112 are exposed, and a plurality of backside bulk insulating films BBI may be formed to respectively fill the plurality of vertical holes. As the plurality of backside bulk insulating films BBI are formed, each of the plurality of fin-type active regions F1 may be divided into a plurality of semiconductor blocks SB that are separated from each other by the plurality of backside bulk insulating films BBI. In some embodiments, to form the plurality of backside bulk insulating films BBI, an ALD process or a chemical vapor deposition (CVD) process may be used, but the inventive concept is not limited thereto.

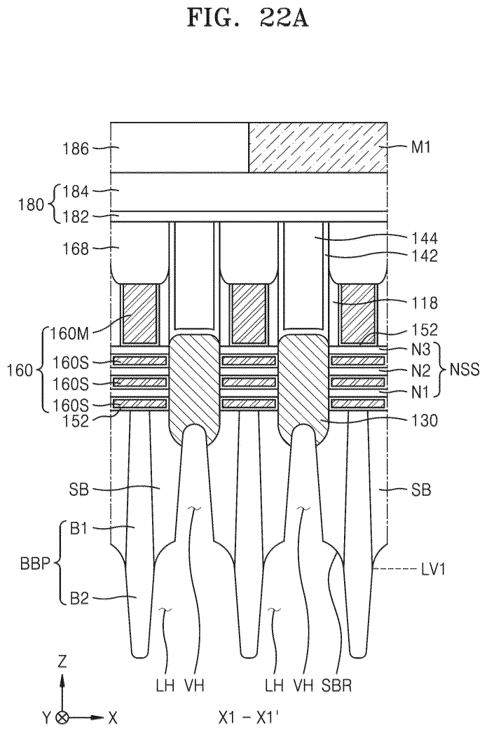

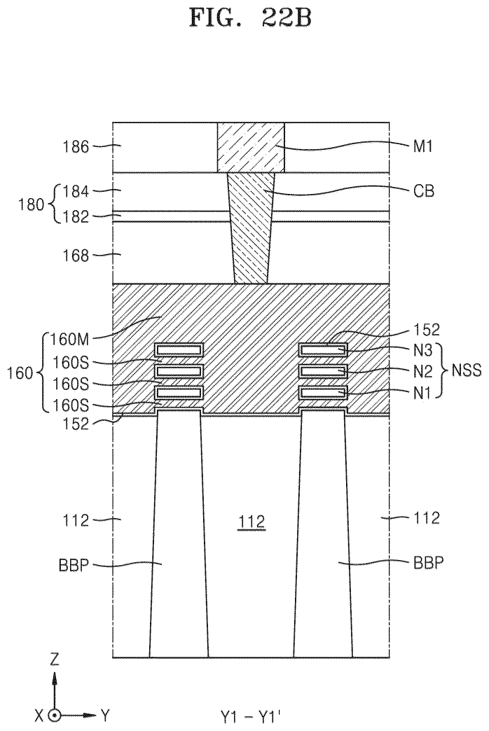

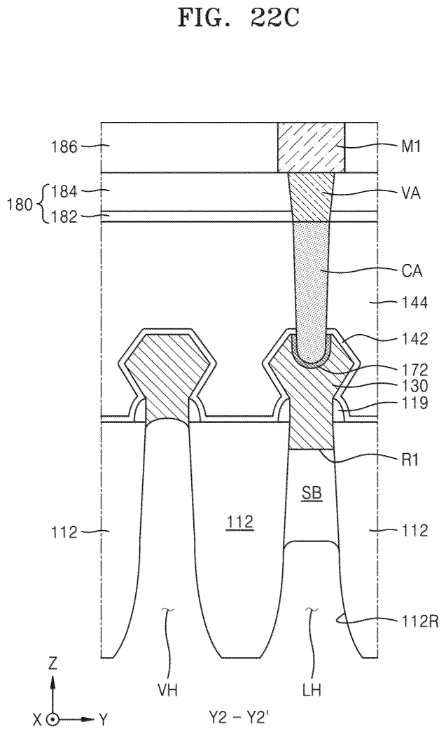

Referring to FIGS. 22A, 22B, and 22C, in the resulting product of FIGS. 21A, 21B, and 21C, a via hole VH, which exposes the source/drain region 130, and a line hole LH, which is connected to the via hole VH, may be formed in each of the plurality of semiconductor blocks SB by partially etching each of the plurality of semiconductor blocks SB. While an etching process for simultaneously forming the via hole VH and the line hole LH is being performed, an exposed portion of each of the device isolation film 112 and the plurality of backside bulk insulating films BBI may be partially etched by using an atmosphere of the etching, whereby a plurality of backside insulating patterns BBP may be formed from the plurality of backside bulk insulating films BBI, and a device isolation curved-surface 112R may be formed in the device isolation film 112. Each of the plurality of backside insulating patterns BBP may include a first backside insulating portion B1 and a second backside insulating portion B2, which are integrally connected to each other. As shown in FIG. 22C, a portion of the line hole LH may not be connected to the via hole VH and may be apart from the source/drain region 130 in the vertical direction (the Z direction) with the semiconductor block SB therebetween.

After the via hole VH and the line hole LH are formed, the first backside insulating portion B1 of each of the plurality of backside insulating patterns BBP may be maintained to be covered by the semiconductor block SB, and the second backside insulating portion B2 of each of the plurality of backside insulating patterns BBP may be exposed by the line hole LH, starting from a first vertical level LV1 at which an end of a contact surface between the semiconductor block SB and the first backside insulating portion B1 is located, the end being farthest from the gate line 160. The width of the second backside insulating portion B2 of each of the plurality of backside insulating patterns BBP in the first horizontal direction (the X direction) may gradually decrease with an increasing distance from the gate line 160 in the vertical direction (the Z direction), and thus, the width of the line hole LH, which is defined by the plurality of second backside insulating portions B2, in the first horizontal direction (the X direction) may gradually increase with an increasing distance from the source/drain region 130 in the vertical direction (the Z direction). Therefore, when a conductive material fills the line hole LH and the via hole VH through the entrance of the line hole LH to simultaneously form the backside via contact BCA and the backside power rail MPR, the insides of the line hole LH and the via hole VH may be easily filled with the conductive material while suppressing the occurrence of defects, such as voids. In addition, because the width, in the first horizontal direction (the X direction), of the backside power rail MPR obtained from the conductive material filling the line hole LH gradually increases with an increasing distance from the source/drain region 130 in the vertical direction (the Z direction) to correspond to the shape of the line hole LH, a volume enough to obtain electrical characteristics required by the backside power rail MPR may be secured, and resistance in the backside power rail MPR may be reduced.

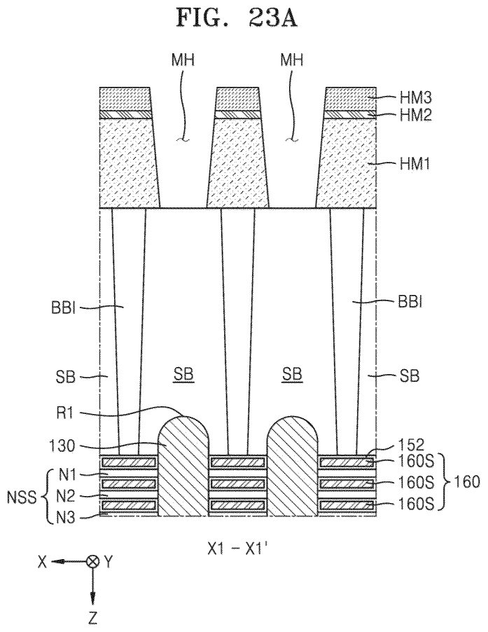

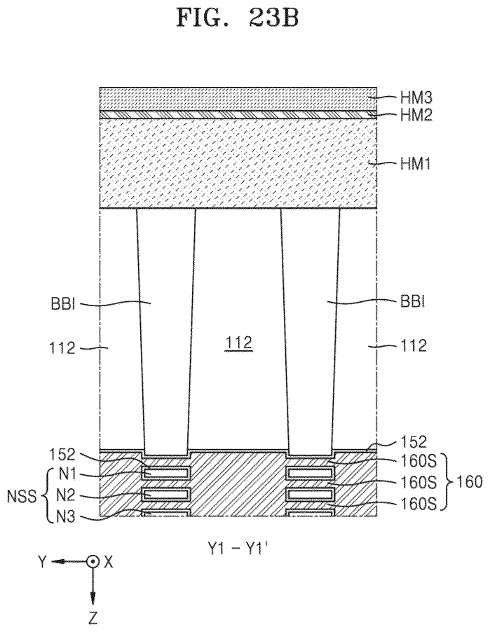

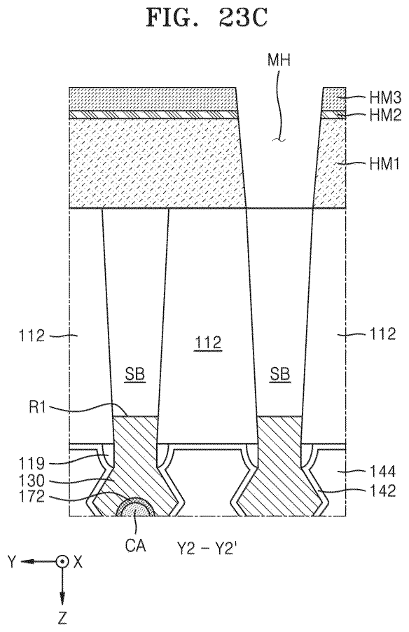

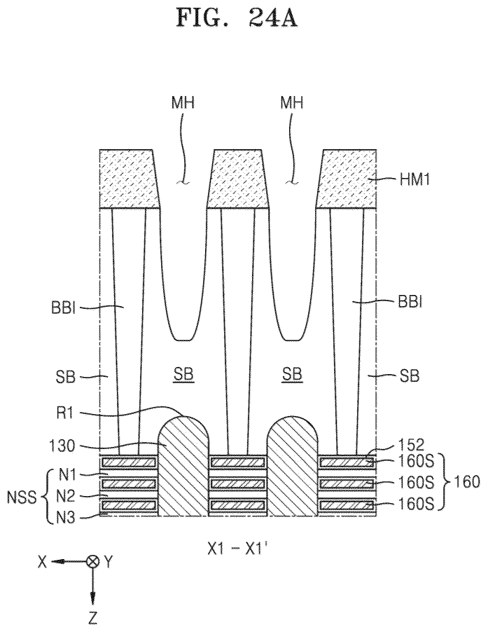

FIGS. 23A to 26C are cross-sectional views illustrating, in more detail, a process of forming the via hole VH and the line hole LH, which are described with reference to FIGS. 22A, 22B, and 22C. More specifically, FIGS. 23A, 24A, 25A, and 26A are cross-sectional views respectively illustrating cross-sectional structures of a region EX11 of FIG. 21A in an area corresponding to the cross-section taken along the line X1-X1′ of FIG. 2, according to a sequence of processes. FIGS. 23B, 24B, 25B, and 26B are cross-sectional views respectively illustrating cross-sectional structures of a region EX12 of FIG. 21B in an area corresponding to the cross-section taken along the line Y1-Y1′ of FIG. 2, according to the sequence of processes. FIGS. 23C, 24C, 25C, and 26C are cross-sectional views respectively illustrating cross-sectional structures of a region EX13 of FIG. 21C in an area corresponding to the cross-section taken along the line Y2-Y2′ of FIG. 2, according to the sequence of processes. For better understanding, FIGS. 23A to 26C illustrate that a process is performed while the resulting product of FIGS. 21A, 21B, and 21C is rotated 180 degrees to be upside down. In FIGS. 23A to 26C, the same reference numerals as in FIGS. 2 to 22C respectively denote the same members, and here, repeated descriptions thereof are omitted.

Referring to FIGS. 23A, 23B, and 23C, in the resulting product of FIGS. 21A, 21B, and 21C, a multilayer-structured hardmask pattern may be formed on the backside surface at which the plurality of semiconductor blocks SB, the plurality of backside bulk insulating films BBI, and the device isolation film 112 are exposed. The multilayer-structured hardmask pattern may include a first hardmask pattern HM1, a second hardmask pattern HM2, and a third hardmask pattern HM3, which are sequentially stacked in the stated order on the backside surface. In some embodiments, the first hardmask pattern HM1 may include a spin-on-hardmask (SOH) material, the second hardmask pattern HM2 may include a silicon oxide film, and the third hardmask pattern HM3 may include a SiON film, but the inventive concept is not limited thereto.

The third hardmask pattern HM3, the second hardmask pattern HM2, and the first hardmask pattern HM1 may be sequentially etched in the stated order, thereby forming a plurality of mask holes MH, which pass through the first hardmask pattern HM1, the second hardmask pattern HM2, and the third hardmask pattern HM3. The plurality of mask holes MH may be formed to respectively correspond to positions at which a plurality of backside via contacts BCA are to be formed. The plurality of semiconductor blocks SB may be exposed by the plurality of mask holes MH.

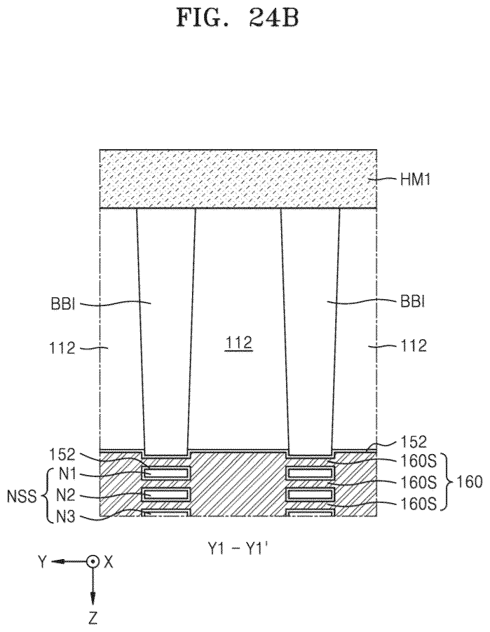

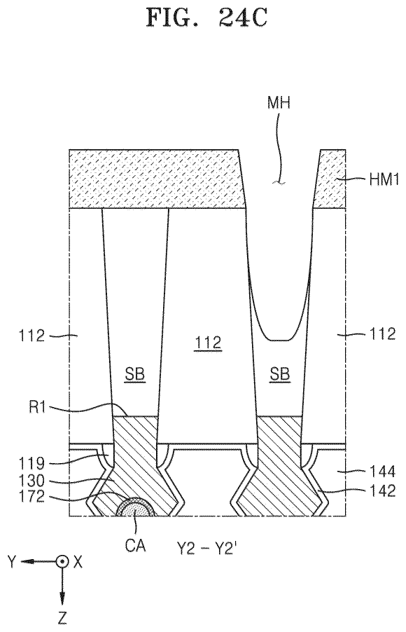

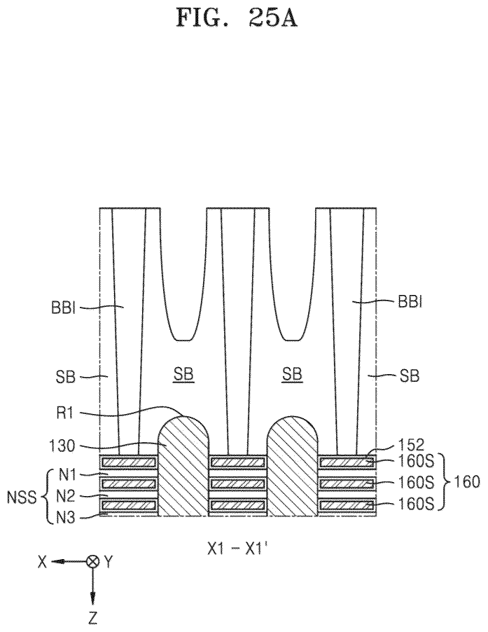

Referring to FIGS. 24A, 24B, and 24C, in the resulting product of FIGS. 23A, 23B, and 23C, each of the plurality of semiconductor blocks SB exposed by the plurality of mask holes MH may be partially etched by using, as an etch mask, the first hardmask pattern HM1, the second hardmask pattern HM2, and the third hardmask pattern HM3. To partially etch each of the plurality of semiconductor blocks SB, a plasma etching process may be performed by using, as an etching gas, a main etching gas including BHr gas and an auxiliary etching gas including a tiny amount of O₂ gas. Because the etching gas includes the auxiliary etching gas including a tiny amount of O₂ gas, excellent vertical anisotropic etching properties may be achieved when each of the plurality of semiconductor blocks SB is etched.

While each of the plurality of semiconductor blocks SB is being partially etched by using, as an etch mask, the first hardmask pattern HM1, the second hardmask pattern HM2, and the third hardmask pattern HM3, the third hardmask pattern HM3, the second hardmask pattern HM2, and a portion of the first hardmask pattern HM1 may be consumed by an etching atmosphere. As a result, after each of the plurality of semiconductor blocks SB is partially etched by as much as an intended depth, only the remaining portion of the first hardmask pattern HM1 after consumption may remain on the backside surface.

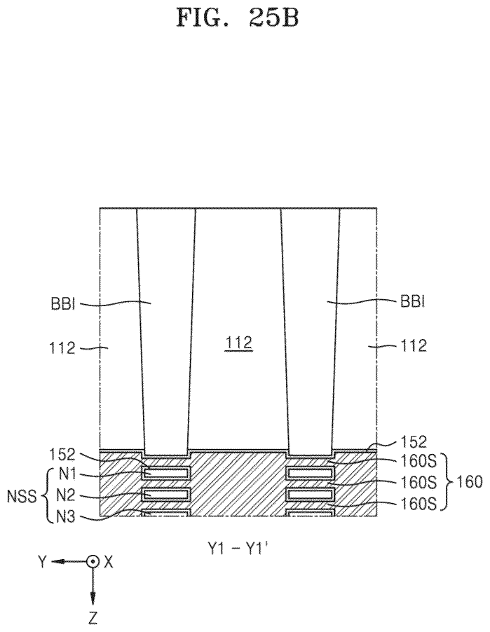

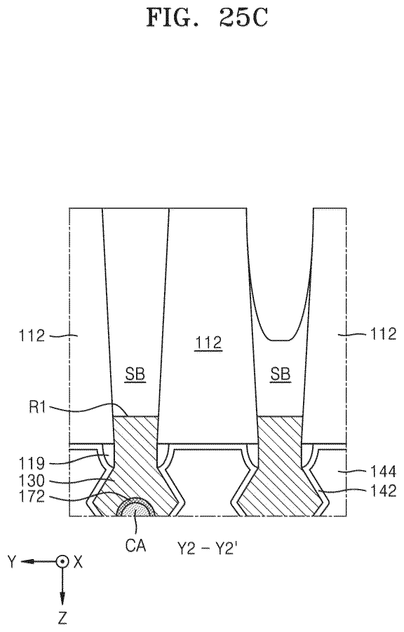

Referring to FIGS. 25A, 25B, and 25C, by removing the first hardmask pattern HM1 remaining on the resulting product of FIGS. 24A, 24B, and 24C, the plurality of semiconductor blocks SB, the plurality of backside bulk insulating films BBI, and the device isolation film 112 may be exposed at the backside surface.

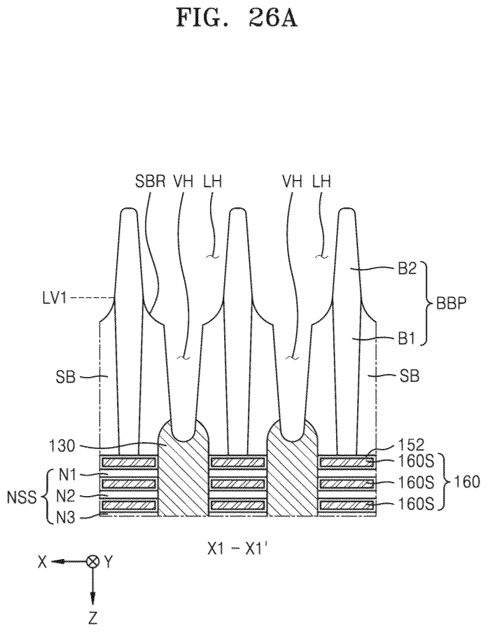

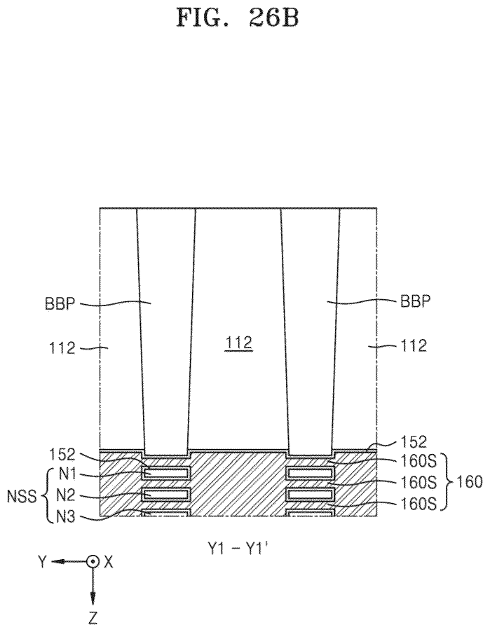

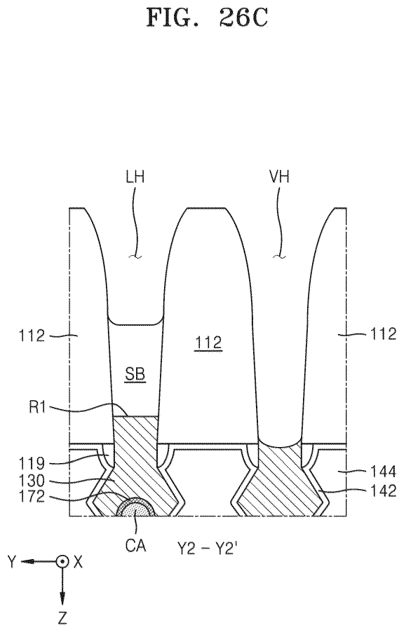

Referring to FIGS. 26A, 26B, and 26C, in the resulting product of FIGS. 25A, 25B, and 25C, the plurality of semiconductor blocks SB may be etched back under the condition that the etch selectivity of the plurality of semiconductor blocks SB is greater than those of the device isolation film 112 and the plurality of backside bulk insulating films BBI, whereby the via hole VH, which exposes the source/drain region 130, and the line hole LH, which is connected to the via hole VH, may be simultaneously formed in each of the plurality of semiconductor blocks SB. While an etching process for simultaneously forming the via hole VH and the line hole LH is being performed, an exposed portion of each of the device isolation film 112 and the plurality of backside bulk insulating films BBI may be partially etched by using an atmosphere of the etching, whereby the plurality of backside insulating patterns BBP may be formed from the plurality of backside bulk insulating films BBI, and the device isolation curved-surface 112R may be formed in the device isolation film 112. As a result, the resulting product shown in FIGS. 22A, 22B, and 22C may be obtained.

To perform the etching process for simultaneously forming the via hole VH and the line hole LH as described with reference to FIGS. 26A, 26B, and 26C, a plasma etching atmosphere obtained from a main etching gas including BHr gas and an auxiliary etching gas including a tiny amount of O₂ gas may be used. Here, by controlling conditions, such as respective flow rates of BHr gas and O₂ gas, an etching process temperature, an etching process pressure, and power, in the plasma etching atmosphere, respective etching amounts of the plurality of semiconductor blocks SB, the plurality of backside bulk insulating films BBI, and the device isolation film 112 may be controlled.

Next, in the resulting product of FIGS. 22A, 22B, and 22C, the plurality of backside via contacts BCA and the plurality of backside power rails MPR may be simultaneously formed by filling the plurality of line holes LH and the plurality of via holes VH with a conductive material through the entrances of the plurality of line holes LH, thereby fabricating the integrated circuit device 100 shown in FIGS. 2 to 6.

Heretofore, although the example of the method of fabricating the integrated circuit device 100 shown in FIGS. 2 to 6 has been described with reference to FIGS. 11A to 26C, it will be understood that the integrated circuit devices 200 and 300 shown in FIGS. 7 to 10 and integrated circuit devices having various structures modified and changed therefrom may be fabricated by making various modifications and changes to the example described with reference to FIGS. 11A to 26C.

For example, to fabricate the integrated circuit device 200 described with reference to FIGS. 7 and 8, similar processes to those described with reference to FIGS. 11A to 26C may be performed. However, after up to the processes described with reference to FIGS. 18A and 18B are performed, before the processes described with reference to FIGS. 19A, 19B, and 19C are performed, a process of forming a trench by removing one gate line 160 selected from the plurality of gate lines 160, the first to third nanosheets N1, N2, and N3 surrounded by the selected one gate line 160, and a portion of the fin-type active region F1 thereunder, and a process of filling the trench with a fin isolation insulating portion 290 may be further performed. Next, the processes described with reference to FIGS. 19A to 26C may be performed, thereby fabricating the integrated circuit device 200 described with reference to FIGS. 7 and 8.

To fabricate the integrated circuit device 300 described with reference to FIGS. 9 and 10, similar processes to those described with reference to FIGS. 11A to 26C may be performed. However, in the processes described with reference to FIGS. 12A and 12B, the plurality of fin-type active regions F1 may be formed to include a series of fin-type active regions F1 that are apart from each other in the second horizontal direction (the Y direction) and arranged in a line in the second horizontal direction (the Y direction). A portion of each of the plurality of sacrificial semiconductor layers 104 and the plurality of nanosheet semiconductor layers NS may remain on or over the fin top surface FF of each of the series of fin-type active regions F1. In addition, in the processes described with reference to FIGS. 13A and 13B, when the device isolation film 112 is formed, the field device isolation film 312 may be formed to fill a space between each of the series of fin-type active regions F1. Next, the processes described with reference to FIGS. 14A to 26C may be performed, thereby fabricating the integrated circuit device 300 described with reference to FIGS. 9 and 10.

Throughout the description horizontal, first horizontal, second horizontal, and vertical directions have been described. These directions may also be referred to as first, second, third, etc. directions with the relationship between them defined, e.g., the first direction is perpendicular to the second direction, or the first and second directions are coplanar.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a gate line;
a source/drain region adjacent to the gate line in a first direction;
a backside via contact connected to the source/drain region;
a backside power rail integrally connected to the backside via contact, the backside power rail spaced apart from the source/drain region in a second direction with the backside via contact therebetween, wherein the second direction is perpendicular to the first direction; and
a backside insulating pattern overlapping the gate line in the second direction, the backside insulating pattern contacting a sidewall of the backside power rail in the first direction,
wherein the backside insulating pattern comprises a first backside insulating portion and a second backside insulating portion, the first backside insulating portion having a gradually increasing width in the first direction with an increasing distance from the gate line, and the second backside insulating portion having a gradually decreasing width in the first direction with an increasing distance from the gate line.

2. The integrated circuit device of claim 1, further comprising a semiconductor block between the first backside insulating portion of the backside insulating pattern and the backside via contact,
wherein the semiconductor block comprises a semiconductor curved-surface contacting the backside power rail.

3. The integrated circuit device of claim 1, wherein the second backside insulating portion of the backside insulating pattern is spaced apart from the gate line in the second direction with the first backside insulating portion therebetween,
the backside power rail is contacting the second backside insulating portion and is separated from the first backside insulating portion, and
the backside via contact is spaced apart from the backside insulating pattern in the first direction.

4. The integrated circuit device of claim 1, wherein the backside power rail has a gradually increasing width in the first direction with an increasing distance from the source/drain region in the second direction.

5. The integrated circuit device of claim 1, further comprising a device isolation film on a sidewall of each of the backside via contact and the backside power rail in a third direction that is perpendicular to the first direction and the second direction and the third direction intersects the first direction,
wherein the backside power rail has a gradually increasing width in the third direction with an increasing distance from the source/drain region in the second direction, and
the device isolation film comprises a device isolation curved-surface contacting the sidewall of the backside power rail in the third direction.

6. The integrated circuit device of claim 1, further comprising a fin isolation insulating portion adjacent to the source/drain region in the first direction, the fin isolation insulating portion spaced apart from the gate line in the first direction with the source/drain region therebetween,
wherein the fin isolation insulating portion comprises a fin isolation curved-surface contacting the sidewall of the backside power rail in the first direction.

7. The integrated circuit device of claim 6, wherein a portion of the fin isolation insulating portion that contacts the backside power rail has an end width defined in the first direction by the fin isolation curved-surface, and,
in the first direction, the end width of the fin isolation insulating portion is less than a width of another portion of the fin isolation insulating portion that does not contact the backside power rail.

8. The integrated circuit device of claim 1, further comprising:
a dummy gate line adjacent to the source/drain region in the first direction, the dummy gate line spaced apart from the gate line in the first direction with the source/drain region therebetween; and
a field device isolation film overlapping the dummy gate line in the second direction,
wherein the field device isolation film comprises a field device isolation curved-surface contacting the sidewall of the backside power rail in the first direction.

9. The integrated circuit device of claim 8, wherein a portion of the field device isolation film that contacts the backside power rail has an end width defined in the first direction by the field device isolation curved-surface, and,
in the first direction, the end width of the field device isolation film is less than a width of another portion of the field device isolation film that does not contact the backside power rail.

10. An integrated circuit device comprising:
a pair of gate lines adjacent to each other in a first direction and each extending in a second direction, wherein the first direction intersects with the second direction;
a source/drain region between the pair of gate lines;
a backside via contact connected to the source/drain region;
a backside power rail integrally connected to the backside via contact, the backside power rail spaced apart from the source/drain region in a third direction with the backside via contact therebetween, wherein the third direction is perpendicular to the first direction and the second direction; and
a pair of backside isolation structures respectively overlapping the pair of gate lines in the third direction,
wherein each of the pair of backside isolation structures is contacting a sidewall of the backside power rail in the first direction, and
at least one backside isolation structure of the pair of backside isolation structures comprises a first backside insulating portion and a second backside insulating portion integrally connected to the first backside insulating portion, the first backside insulating portion having a gradually increasing width in the first direction with an increasing distance from a gate line of the pair of gate lines, and the second backside insulating portion having a gradually decreasing width in the first direction with an increasing distance from the gate line.

11. The integrated circuit device of claim 10, further comprising a semiconductor block between the first backside insulating portion of the at least one backside isolation structure and the backside via contact,
wherein the semiconductor block comprises a semiconductor curved-surface contacting the backside power rail.

12. The integrated circuit device of claim 10, wherein, in each of the pair of backside isolation structures, a width of a portion contacting the sidewall of the backside power rail, in the first direction, gradually decreases with an increasing distance from the gate line in the third direction.

13. The integrated circuit device of claim 10, wherein the backside power rail has a gradually increasing width in the first direction with an increasing distance from the source/drain region in the third direction, and
opposing sidewalls of the backside power rail in the first direction have asymmetric shapes relative to each other.

14. The integrated circuit device of claim 10, further comprising a device isolation film on a sidewall of each of the backside via contact and the backside power rail in the second direction,
wherein the backside power rail has a gradually increasing width in the second direction with an increasing distance from the source/drain region in the third direction, and
the device isolation film comprises a device isolation curved-surface contacting the sidewall of the backside power rail in the second direction.

15. The integrated circuit device of claim 10, wherein
another backside isolation structure of the pair of backside insulating patterns comprises a first backside insulating portion and a second backside insulating portion, and,
in the first direction, a cross-sectional shape of the backside power rail comprises two side portions symmetric to each other about a central axis, that extends in the third direction, of the backside via contact.

16. The integrated circuit device of claim 10, wherein one of the pair of gate lines comprises a dummy gate line,
one of the pair of backside isolation structures comprises a backside insulating pattern including the first backside insulating portion and the second backside insulating portion,
the other of the pair of backside isolation structures comprises a field device isolation film overlapping the dummy gate line in the third direction, and
the field device isolation film comprises a field device isolation curved-surface contacting the sidewall of the backside power rail in the first direction.

17. The integrated circuit device of claim 10, further comprising:
a fin isolation insulating portion spaced apart from the pair of gate lines in the first direction; and
another backside power rail contacting the fin isolation insulating portion and spaced apart from the backside power rail in the first direction,
wherein the fin isolation insulating portion comprises a fin isolation curved-surface contacting a sidewall of the another backside power rail in the first direction.

18. An integrated circuit device comprising:
a pair of gate lines adjacent to each other in a first direction and each extending in a second direction, wherein the first direction intersects with the second direction;
a plurality of source/drain regions comprising a first source/drain region between the pair of gate lines;
a plurality of backside via contacts comprising a first backside via contact connected to the first source/drain region;
a plurality of backside power rails comprising a first backside power rail integrally connected to the first backside via contact, the first backside power rail spaced apart from the first source/drain region in a third direction with the first backside via contact therebetween, wherein the third direction is perpendicular to the first direction and the second direction;
a pair of backside insulating patterns respectively overlapping the pair of gate lines in the third direction; and
a pair of semiconductor blocks each arranged between the first backside via contact and each of the pair of backside insulating patterns,
wherein a portion of each of the pair of backside insulating patterns contacts a respective sidewall of the first backside power rail in the first direction,
each of the pair of backside insulating patterns comprises a first backside insulating portion and a second backside insulating portion integrally connected to the first backside insulating portion, the first backside insulating portion having a gradually increasing width in the first direction with an increasing distance from a gate line of the pair of gate lines, and the second backside insulating portion having a gradually decreasing width in the first direction with an increasing distance from the gate line, and
each of the pair of semiconductor blocks comprises a semiconductor curved-surface that contacts the first backside power rail.

19. The integrated circuit device of claim 18, wherein the first backside power rail contacts the second backside insulating portion and is separated from the first backside insulating portion of each of the pair of backside insulating patterns.

20. The integrated circuit device of claim 18, wherein the plurality of backside power rails further comprise a second backside power rail spaced apart from the first backside power rail in the first direction,
the first backside power rail has a gradually increasing width in the first direction with an increasing distance from the first source/drain region in the third direction,
the second backside power rail has a gradually increasing width in the first direction with an increasing distance from a second source/drain region in the third direction among the plurality of source/drain regions, the second source/drain region corresponding to the second backside power rail,
opposing sidewalls of the first backside power rail in the first direction have symmetric shapes relative to each other, and
opposing sidewalls of the second backside power rail in the first direction have asymmetric shapes relative to each other.
